(19) United States
(12) Patent Application Publication
(10) Pub. No.: US 2025/0271524 A1
(43) Pub. Date: Aug. 28, 2025

(54) METHODS FOR PROTON-ONLY DETECTION OF HYPERPOLARIZED HETERONUCLEAR SINGLET STATES

(71) Applicants: North Carolina State University, Raleigh, NC (US); Wayne State University, Detroit, MI (US)

(72) Inventors: Thomas Theis, Raleigh, NC (US); Iuliia Mandzhieva, Raleigh, NC (US); Isaiah Adelabu, Detroit, MI (US); Eduard Y. Chekmenev, Detroit, MI (US)

(21) Appl. No.: 18/858,353

(22) PCT Filed: Apr. 20, 2023
(86) PCT No.: PCT/US2023/065984

§ 371 Date: Oct. 21, 2024

Related U.S. Application Data
(60) Provisional application No. 63/363,410, filed on Apr. 22, 2022.

(51) Int. Cl. G01R 33/56; A61B 5/055; A61K 49/10

(52) U.S. Cl. CPC G01R 33/5601; A61K 49/103; A61B 5/055

(57) ABSTRACT

In one aspect, the disclosure relates to a method for hyperpolarizing the long-lived singlet state of ¹³C₂ pyruvate with parahydrogen and transferring the polarization to methyl pyruvate protons for detection, or to protons in other target analytes having a long-lived hyperpolarized singlet state and protons weakly couple into the singlet spin pair. In a further aspect, the method can be conducted on conventional, proton-only MRI systems. This abstract is intended as a scanning tool for purposes of searching in the particular art and is not intended to be limiting of the present disclosure.

### CROSS-REFERENCE TO RELATED APPLICATIONS

This application claims the benefit of U.S. Provisional Application No. 63/363,410, filed on Apr. 22, 2022, which is incorporated herein by reference in its entirety.

### STATEMENT REGARDING FEDERALLY SPONSORED RESEARCH OR DEVELOPMENT

This invention was made with government support under grant number EB029829, awarded by the National Institutes of Health. The government has certain rights in the invention.

### BACKGROUND

Current metabolic imaging is dominated by positron emission tomography (PET) and single photon emission computerized tomography (SPECT), but the emerging field of hyperpolarized magnetic resonance imaging (MRI) makes the tracking of biomolecular metabolism to elucidate disease states such as cancer in real time accessible beyond radioisotope imaging. Pyruvate has emerged as a leading initial candidate for hyperpolarized metabolic imaging due to its central role in metabolism. Specifically, pyruvate metabolism to lactate is emphasized in cancer cells, enabling early metabolic detection of cancer cells. However, current methods and systems for hyperpolarized MRI require specialized multinuclear MRI scanners that have the ability to excite and detect ¹³C signals.

Traditional MRI only detects water or fat, or more generally speaking, molecules at high concentration. Molecules at low concentration cannot be detected easily. As a result, MRI is viewed as a technique to image structure, not function, because the molecules that report on biochemical function are at low concentration and typically remain below MRI instruments' sensitivity thresholds. With hyperpolarization, the molecules at low concentration become detectable, and information on their biochemical transformations can be obtained. In the context of radiology and diagnostics, it is important to note that disruptions in metabolic signaling precede changes in structure. Therefore, hyperpolarized MRI can be used for early stage detection of various diseases, including cancer, diabetes, and cardiovascular disease. Additionally, hyperpolarized MRI can be used for safe, continuous treatment monitoring and offers more valuable information than simple changes in structure such as, for example, tumor size. Instead, changes in metabolism are detectable, which is a much better marker of treatment efficacy.

Many diseases manifest as metabolic responses far before diseased structural features emerge, opening a window for possible early diagnosis and treatment. Furthermore, patient responses to treatment can manifest as changes to local metabolism before corresponding changes become visible in anatomical images; thus, realization of metabolic imaging may provide earlier indications of treatment success or failure relative to conventional imaging. Current MRI scanners are unable to image these metabolic changes due to the combined low concentration and low thermal spin polarization (P<0.001%) of these molecules. Hyperpolarization is a broad field that attempts to address these inherent limitations of traditional MRI, accessing high polarization (P>1%) and enabling imaging of endogenous metabolites such as pyruvate at physiologically relevant concentrations.

Despite advances in hyperpolarization research, there is still a scarcity of methods that allow for the detection of hyperpolarized ¹³C signals in pyruvate and other target analytes to a level compatible with real-time MRI imaging in subjects. Such methods would work in conventional (i.e., proton only) MRI systems while taking advantage of long-lived ¹³C hyperpolarization, thus allowing widespread use of the methods in medical and other research settings. These needs and other needs are satisfied by the present disclosure.

### SUMMARY

In accordance with the purpose(s) of the present disclosure, as embodied and broadly described herein, the disclosure, in one aspect, relates to a method for hyperpolarizing the long-lived singlet state of ¹³C₂ pyruvate with parahydrogen and transferring the polarization to methyl pyruvate protons for detection, or to protons in other target analytes having a long-lived hyperpolarized singlet state and protons weakly couple into the singlet spin pair. In a further aspect, the method can be conducted on conventional, proton-only MRI systems.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1A shows SABRE catalytically transfers magnetization from p-H₂ to a substrate ([¹³C_{1,2}]-pyruvate) through a temporary J-coupled network when both p-H₂ and substrate are in reversible exchange with a polarization transfer complex Ir(IMes)(COD)Cl. FIG. 1B shows ¹³C NMR spectrum of [¹³C_{1,2}]-pyruvate at 9.4 T. FIG. 1C shows SLIC pulse applied only on proton channel drives polarization from singlet carbon state to proton on methyl group. FIG. 1D shows a pulse sequence for linear ramp SLIC pulse for polarization transfer and signal detection along the z-direction.

FIGS. 2A-2F show SLIC simulations for 1,2-[¹³C₂] Pyruvate of (FIG. 2A) B1 sweep of square pulse with 230 and 100 ms duration on resonance (Ω⁰=0 Hz) for 3 and 5 spin systems respectively, on resonance; (FIG. 2B) Pulse duration sweep of square pulse with signal amplitude of 63 Hz on resonance (Ω⁰=0 Hz) (FIG. 2C) B1 sweep of square pulse with 230 and 150 ms duration off resonance (Ω⁰=45 Hz) for 3 and 5 spin systems respectively, off resonance; (FIG. 2D) Pulse duration sweep of square pulse with signal amplitude of 44 Hz off resonance (Ω⁰=45 Hz); (FIG. 2E) linear ramp pulse with initial signal amplitude of 150 Hz on resonance (Ω⁰=0 Hz) and duration 2 s; (FIG. 2F) linear ramp pulse with initial signal amplitude of 150 Hz off resonance (Ω⁰=45 Hz). Key in FIG. 2A applies to all of FIGS. 2A-2F.

FIG. 3A shows experimental proof of the concept of proton-only detection of a hyperpolarized carbon singlet of ¹³C₂-pyruvate. FIGS. 3B-3D show characterization of the system as a function of B₁ power (FIG. 3B), pulse duration (FIG. 3C), and irradiation frequency (FIG. 3D).

FIG. 4A shows S2M or R4₃¹ pulse applied only on proton channel drives polarization from ¹³C₂ pyruvate singlet to methyl protons; FIG. 4B shows S2M pulse sequence, FIG. 4C shows S2M composite pulse sequence; FIG. 4D shows R4₃¹ pulse sequence.

FIG. 5A shows a simulated ¹H magnetization intensity after application of a S2M pulses to singlet-hyperpolarized [1,2-¹³C₂]pyruvate. (FIG. 5B) T sweep acquired after S2M pulse with 2.01885 MHz frequency and N=17. (FIG. SC) Simulated T sweep acquired after S2M pulse with N=17. (FIG. 5D) N sweep acquired after S2M pulse with 2.01885 MHz frequency and tau=3.97 ms. (FIG. 5E) Simulated N sweep acquired after S2M pulse with tau=3.97 ms. (FIG. 5F) 90° angle sweep acquired after S2M pulse with 2.01885 MHz, tau=3.97 ms and N=17. (FIG. 5G) Simulated 90° angle sweep acquired after S2M pulse with tau=3.97 ms and N=17.

FIG. 6A shows a simulated ¹H magnetization intensity after application of a S2M composite pulses to singlet-hyperpolarized [1,2-¹³C₂]pyruvate. (FIG. 6B) T sweep acquired after S2M composite pulse with 2.01885 MHz frequency and N=17. (FIG. 6C) Simulated T sweep acquired after S2M composite pulse with N=17. (FIG. 6D) N sweep acquired after S2M composite pulse with 2.01885 MHz frequency and tau=3.97 ms. (FIG. 6E) Simulated N sweep acquired after S2M composite pulse with tau=3.97 ms. (FIG. 6F) 90° angle sweep acquired after S2M composite pulse with 2.01885 MHz, tau=3.97 ms and N=17. (FIG. 6G) Simulated 90° angle sweep acquired after S2M composite pulse with tau=3.97 ms and N=17.

FIG. 7A shows a simulated ¹H magnetization intensity after application of R4₃¹ pulses to singlet-hyperpolarized [1,2-¹³C₂]pyruvate. (FIG. 7B) T sweep acquired after R4₃¹ pulses with 2.01885 MHz frequency and N=5. (FIG. 7C) Simulated T sweep acquired after R4₃¹ pulses with N=5. (FIG. 7D) N sweep acquired after R4₃¹ pulses with 2.01885 MHz frequency and tau=5.95 ms. (FIG. 7E) Simulated N sweep acquired after R4₃¹ pulses with tau=5.95 ms. (FIG. 7F) 90° angle sweep acquired after R4₃¹ pulses with 2.01885 MHz, tau=5.95 ms and N=5. (FIG. 7G) Simulated 90° angle sweep acquired after R4₃¹ pulses with tau=3.97 ms and N=17.

FIG. 8A shows frequency offset sweep acquired after S2M pulses with tau=3.97 ms and N=17 (FIG. 8B) Frequency offset sweep acquired after S2M composite pulses with tau=3.97 ms and N=17 (FIG. 8C) Frequency offset sweep acquired after R4₃¹ pulses with tau=5.95 ms and N=5.

FIGS. 9A-9B show simulations for a B₀=6.5×10⁻³ T magnetic field for the purpose of optimization of z-magnetization using the pulse sequence of FIG. 4B. The optimum number of pulses was determined to be N=7, with T=4.25 (time delay between pulses) and a time step of 30 μs.

FIG. 10A shows an overall view of xy-magnetization, where on the plot, x is T, y is the number of pulses, and z is xy-magnetization in arbitrary units for the system described in FIGS. 9A-9B. FIG. 10B shows dependence of z-magnetization on T. FIG. 10C shows dependence of z-magnetization on number of pulses.

FIGS. 11A-11B show an MLEV-16 pulse sequence useful herein, where T=7.75 ms is the optimum value.

FIGS. 12A-12B show the effect of pulse angle (MLEV-15) on z-magnetization at optimum parameters using the system shown in FIGS. 11A-11B.

FIG. 13 shows pulse program considerations related to correction for pulse thickness including correction factor of T′/2 time delay between pulses.

Additional advantages of the invention will be set forth in part in the description which follows, and in part will be obvious from the description, or can be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### DETAILED DESCRIPTION

Conventionally, it has been accepted that hyperpolarized ¹³C nuclei could only be detected with radio frequency (RF) irradiation on the ¹³C Larmor frequency. Disclosed herein is a method for detection of hyperpolarized ¹³C signals without RF irradiation at the ¹³C Larmor frequency. In one aspect, the method allows hyperpolarized MRI to be conducted on standard, proton-only MRI scanners. In some aspects, the disclosed method works for pyruvate but also other molecules where a long-lived singlet state is hyperpolarized and protons weakly couple into the singlet spin pair.

In another aspect, the disclosed methods offer increased sensitivity over previously-known methods. In a further aspect, the disclosed methods can also be used for molecular imaging in other organisms and biological systems including, but not limited to, plants, cell cultures, and the like. In still another aspect, the disclosed methods can enhance nuclear magnetic resonance (NMR) modalities for chemical analysis. In a still further aspect, detection using the disclosed methods can occur not only with traditional NMR and MRI techniques but can also occur with other sensitive magnetometers including, but not limited to, Rb-vapor magnetometers, NV-diamond quantum sensors, and other emerging techniques.

In one aspect, disclosed herein is a method for proton-only detection of hyperpolarized spin ½ nucleus in a target analyte, the method including at least the steps of: (a) hyperpolarizing parahydrogen; (b) transferring magnetization from the parahydrogen to a spin ½ nucleus in a target analyte; (c) applying a pulse sequence on a proton channel, wherein the pulse sequence drives polarization from a singlet carbon state in the spin ½ nucleus to at least one proton coupled to a the spin ½ nucleus in the target analyte; and (d) detecting a signal from the at least one proton. In one aspect, the spin ½ nucleus can be selected from ¹³C, ¹⁵N, ¹⁹F, ²⁹Si, ³¹P, or a combination thereof and magnetization can be transferred from the parahydrogen using a spin lock induced crossing (SLIC) or magnetization to singlet (M2S) pulse sequence. Also disclosed are hyperpolarized target analytes prepared by the disclosed method, contrast agents containing the hyperpolarized target analytes, and methods for diagnosing and/or monitoring the progress of treatment of diseases in the subject, the methods including the step of administering the contrast agents to the subject and then performing imaging on the subject.

Many modifications and other embodiments disclosed herein will come to mind to one skilled in the art to which the disclosed compositions and methods pertain having the benefit of the teachings presented in the foregoing descriptions and the associated drawings. Therefore, it is to be understood that the disclosures are not to be limited to the specific embodiments disclosed and that modifications and other embodiments are intended to be included within the scope of the appended claims. The skilled artisan will recognize many variants and adaptations of the aspects described herein. These variants and adaptations are intended to be included in the teachings of this disclosure and to be encompassed by the claims herein.

Although specific terms are employed herein, they are used in a generic and descriptive sense only and not for purposes of limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure.

Any recited method can be carried out in the order of events recited or in any other order that is logically possible. That is, unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present invention is not entitled to antedate such publication by virtue of prior invention. Further, the dates of publication provided herein can be different from the actual publication dates, which can require independent confirmation.

While aspects of the present disclosure can be described and claimed in a particular statutory class, such as the system statutory class, this is for convenience only and one of skill in the art will understand that each aspect of the present disclosure can be described and claimed in any statutory class.

It is also to be understood that the terminology used herein is for the purpose of describing particular aspects only and is not intended to be limiting. Unless defined otherwise, all technical and scientific terms used herein have the same meaning as commonly understood by one of ordinary skill in the art to which the disclosed compositions and methods belong. It will be further understood that terms, such as those defined in commonly used dictionaries, should be interpreted as having a meaning that is consistent with their meaning in the context of the specification and relevant art and should not be interpreted in an idealized or overly formal sense unless expressly defined herein.

Prior to describing the various aspects of the present disclosure, the following definitions are provided and should be used unless otherwise indicated. Additional terms may be defined elsewhere in the present disclosure.

### Definitions

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by,” “comprising,” “comprises”, “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.

As used in the specification and the appended claims, the singular forms “a,” “an” and “the” include plural referents unless the context clearly dictates otherwise. Thus, for example, reference to “a solvent,” “a polarization transfer catalyst,” or “a co-ligand,” include, but are not limited to, mixtures or combinations of two or more such solvents, polarization transfer catalysts, or co-ligands, and the like.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

When a range is expressed, a further aspect includes from the one particular value and/or to the other particular value. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y.’ The range can also be expressed as an upper limit, e.g. ‘about x, y, z, or less’ and should be interpreted to include the specific ranges of ‘about x,’ ‘about y’, and ‘about z’ as well as the ranges of ‘less than x’, less than y’, and ‘less than z’. Likewise, the phrase ‘about x, y, z, or greater’ should be interpreted to include the specific ranges of ‘about x,’ ‘about y,’ and ‘about z’ as well as the ranges of ‘greater than x,’ greater than y,’ and ‘greater than z.’ In addition, the phrase “about ‘x’ to ‘y’”, where ‘x’ and ‘y’ are numerical values, includes “about ‘x’ to about ‘y’.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the terms “about,” “approximate,” “at or about,” and “substantially” mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

As used herein, the term “effective amount” refers to an amount that is sufficient to achieve the desired modification of a physical property of the composition or material. For example, an “effective amount” of a polarization transfer catalyst refers to an amount that is sufficient to achieve the desired improvement in the property modulated by the formulation component, e.g. achieving the desired level of hyperpolarization. The specific level in terms of wt % in a composition required as an effective amount will depend upon a variety of factors including the amount and type of catalyst, amount and type of target analyte or substrate, amount and type of solvent, and presence and identity of any co-ligands.

As used herein, the terms “optional” or “optionally” means that the subsequently described event or circumstance can or cannot occur, and that the description includes instances where said event or circumstance occurs and instances where it does not.

Unless otherwise specified, temperatures referred to herein are based on atmospheric pressure (i.e. one atmosphere).

“Thermal polarization” as used herein refers to the fraction of nuclear spins that align with a magnetic field under normal conditions. This is typically a small number and can be measured in units of parts per million (ppm), even in a strong magnetic field.

By contrast, “hyperpolarization” refers to nuclear spin polarization far beyond thermal equilibrium conditions. In one aspect, hyperpolarization aligns almost all spins with the magnetic field, achieving signal enhancements of up to 10,000,000-fold when compared to thermal polarization.

“Orthohydrogen” (o-H₂) is an isomeric form of molecular hydrogen. In o-H₂, the spins of both nuclei are symmetrically aligned. In one aspect, at room temperature and thermal equilibrium, approximately 75% of an H₂ sample is in the orthohydrogen (triplet) state.

“Parahydrogen” (p-H₂) is a second isomeric form of molecular hydrogen. In p-H₂, the spins of both nuclei are anti-symmetrically aligned. In one aspect, at room temperature and thermal equilibrium, approximately 25% of an H₂ sample is in the parahydrogen (singlet) state. In a further aspect, use of parahydrogen exhibits hyperpolarized signals in NMR spectra. In one aspect, the reactor and process disclosed herein use parahydrogen to induce transfer spin in order to induce hyperpolarization in samples for NMR and MRI analysis. “Parahydrogen Induced Polarization” or “PHIP” is a hyperpolarization technique using p-H₂ as a source of spin transfer for inducing hyperpolarization. In one aspect, PHIP involves chemical reaction of p-H₂.

“Signal amplification by reversible exchange” or “SABRE” is a technique that can increase the visibility of compounds for the purpose of NMR and MRI analysis, which in turn allows lower detection limits and shorter scan times in NMR, as well as higher contrast and higher resolution in MRI imaging. In one aspect, a metal-containing catalyst transfers spin from parahydrogen to a substrate, which can then be imaged or analyzed as appropriate.

As used herein, a “polarization transfer catalyst” is a metal containing catalyst that transiently binds both a substrate molecule and p-H₂, thereby allowing polarization to transfer from the p-H₂ to the substrate in a magnetic field. In some aspects, the metal in the polarization transfer catalyst is iridium. In another aspect, the iridium is typically coordinated with species containing aromatic rings and/or nitrogen heterocycles.

In some aspects, a “co-ligand” can be used in the disclosed methods. As used herein, “co-ligand” refers to a molecule capable of coordinating with the metal center in a polarization transfer catalyst. A co-ligand can, in some aspects, enhance polarization transfer efficiency to a target analyte, or can enhance binding efficiency of target analyte to the polarization transfer catalyst, or any combination thereof. Useful co-ligands disclosed herein include, but are not limited to, DMSO, water, and combinations thereof.

As used herein, “substrate” and “target analyte” refer to a molecule or chemical species to which polarization transfer is desired. Substrate and/or target analytes may be bound to a polarization transfer catalyst, may be free in solution, or a combination thereof.

As used interchangeably herein, “subject,” “individual,” or “patient” can refer to a vertebrate organism, such as a mammal (e.g. human). “Subject” can also refer to a cell, a population of cells, a tissue, an organ, or an organism, preferably to human and constituents thereof.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc. It is also contemplated that, in certain aspects, unless expressly indicated to the contrary, individual substituents can be further optionally substituted (i.e., further substituted or unsubstituted).

The term “alkyl” as used herein is a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic or acyclic. The alkyl group can be branched or unbranched. The alkyl group can also be substituted or unsubstituted. For example, the alkyl group can be substituted with one or more groups including, but not limited to, alkyl, cycloalkyl, alkoxy, amino, ether, halide, hydroxy, nitro, silyl, sulfo-oxo, or thiol, as described herein. A “lower alkyl” group is an alkyl group containing from one to six (e.g., from one to four) carbon atoms. The term alkyl group can also be a C1 alkyl, C1-C2 alkyl, C1-C3 alkyl, C1-C4 alkyl, C1-C5 alkyl, C1-C6 alkyl, C1-C7 alkyl, C1-C8 alkyl, C1-C9 alkyl, C1-C10 alkyl, and the like up to and including a C1-C24 alkyl.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” or “haloalkyl” specifically refers to an alkyl group that is substituted with one or more halide, e.g., fluorine, chlorine, bromine, or iodine. Alternatively, the term “monohaloalkyl” specifically refers to an alkyl group that is substituted with a single halide, e.g. fluorine, chlorine, bromine, or iodine. The term “polyhaloalkyl” specifically refers to an alkyl group that is independently substituted with two or more halides, i.e. each halide substituent need not be the same halide as another halide substituent, nor do the multiple instances of a halide substituent need to be on the same carbon. The term “alkoxyalkyl” specifically refers to an alkyl group that is substituted with one or more alkoxy groups, as described below. The term “aminoalkyl” specifically refers to an alkyl group that is substituted with one or more amino groups. The term “hydroxyalkyl” specifically refers to an alkyl group that is substituted with one or more hydroxy groups. When “alkyl” is used in one instance and a specific term such as “hydroxyalkyl” is used in another, it is not meant to imply that the term “alkyl” does not also refer to specific terms such as “hydroxyalkyl” and the like.

This practice is also used for other groups described herein. That is, while a term such as “cycloalkyl” refers to both unsubstituted and substituted cycloalkyl moieties, the substituted moieties can, in addition, be specifically identified herein; for example, a particular substituted cycloalkyl can be referred to as, e.g., an “alkylcycloalkyl.” Similarly, a substituted alkoxy can be specifically referred to as, e.g., a “halogenated alkoxy,” a particular substituted alkenyl can be, e.g., an “alkenylalcohol,” and the like. Again, the practice of using a general term, such as “cycloalkyl,” and a specific term, such as “alkylcycloalkyl,” is not meant to imply that the general term does not also include the specific term.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, norbornyl, and the like. The term “heterocycloalkyl” is a type of cycloalkyl group as defined above, and is included within the meaning of the term “cycloalkyl,” where at least one of the carbon atoms of the ring is replaced with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, alkyl, cycloalkyl, alkoxy, amino, ether, halide, hydroxy, nitro, silyl, sulfo-oxo, or thiol as described herein.

The term “aryl” as used herein is a group that contains any carbon-based aromatic group including, but not limited to, benzene, naphthalene, phenyl, biphenyl, anthracene, and the like. The aryl group can be substituted or unsubstituted. The aryl group can be substituted with one or more groups including, but not limited to, alkyl, cycloalkyl, alkoxy, alkenyl, cycloalkenyl, alkynyl, cycloalkynyl, aryl, heteroaryl, aldehyde, —NH₂, carboxylic acid, ester, ether, halide, hydroxy, ketone, azide, nitro, silyl, sulfo-oxo, or thiol as described herein. The term “biaryl” is a specific type of aryl group and is included in the definition of “aryl.” In addition, the aryl group can be a single ring structure or comprise multiple ring structures that are either fused ring structures or attached via one or more bridging groups such as a carbon-carbon bond. For example, biaryl to two aryl groups that are bound together via a fused ring structure, as in naphthalene, or are attached via one or more carbon-carbon bonds, as in biphenyl.

Now having described the aspects of the present disclosure, in general, the following Examples describe some additional aspects of the present disclosure. While aspects of the present disclosure are described in connection with the following examples and the corresponding text and figures, there is no intent to limit aspects of the present disclosure to this description. On the contrary, the intent is to cover all alternatives, modifications, and equivalents included within the spirit and scope of the present disclosure.

### ASPECTS

The present disclosure can be described in accordance with the following numbered Aspects, which should not be confused with the claims.

Aspect 1. A method for proton-only detection of a hyperpolarized spin ½ nucleus in a target analyte, the method comprising:
(a) hyperpolarizing parahydrogen;
(b) transferring magnetization from the parahydrogen to a spin ½ nucleus in a target analyte;
(c) applying a pulse sequence on a proton channel, wherein the pulse sequence drives polarization from a singlet state in the spin ½ nucleus to at least one proton coupled to the spin ½ nucleus in the target analyte or to another coupled spin; and
(d) detecting a signal from the at least one proton.

Aspect 2. The method of aspect 1, wherein the spin ½ nucleus comprises ¹³C, ¹⁵N, ¹⁹F, ²⁹Si, ³¹P, or a combination thereof.

Aspect 3. The method of aspect 1 or 2, wherein the pulse sequence comprises spin lock induced crossing (SLIC), magnetization to singlet (M2S), singlet to magnetization (S2M), S2M composite, R4₃¹, or any combination thereof.

Aspect 4. The method of aspect 3, wherein the pulse sequence is S2M, the method further comprising applying a 90° pulse following the S2M pulse.

Aspect 5. The method of any one of aspects 1-4, wherein the target analyte comprises metabolite, a drug molecule, a vitamin, a pyruvate analog, a combination thereof, or a salt thereof.

Aspect 6. The method of aspect 5, wherein the salt comprises a sodium salt or a disodium salt.

Aspect 7. The method of aspect 5, wherein the pyruvate analog comprises pyruvate, oxaloglutarate, oxaloacetate, phenyl pyruvate, 2-oxo-butyrate, 2,3-diketogluatarate, 2-oxo-adipate, or any combination thereof.

Aspect 8. The method of aspect 5, wherein the target analyte comprises acetonitrile, benzonitrile, α-cyano-4-hydroxycinnamic acid (CHCA), alectinib, metronidazole, dichloropyridazine, nicotinamide, imidazole, adenine, diphenyldiazene, diazirine, or any combination thereof.

Aspect 9. The method of aspect 5, wherein the target analyte includes a Schiff base, an sp² hybridized nitrogen atom, or any combination thereof.

Aspect 10. The method of any one of aspects 1-9, wherein transferring magnetization comprises a parahydrogen induced polarization (PHIP) mechanism.

Aspect 11. The method of aspect 10, wherein the PHIP mechanism comprises hydrogenation, signal amplification by reversible exchange (SABRE), or any combination thereof.

Aspect 12. The method of any one of the preceding aspects, wherein the parahydrogen has at least 25% purity.

Aspect 13. The method of aspect 12, wherein the parahydrogen has at least 50% purity.

Aspect 14. The method of any one of the preceding aspects, wherein the parahydrogen has a pressure of from about 15 psi (103 kPa) to about 15,000 psi (103 MPa).

Aspect 15. The method of aspect 14, wherein the parahydrogen has a pressure of from about 75 psi (517 kPa) to about 200 psi (1379 kPa).

Aspect 16. The method of aspect 14, wherein the parahydrogen has a pressure of about 100 psi (690 kPa).

Aspect 17. The method of any one of the preceding aspects, wherein transferring magnetization from the parahydrogen to the target analyte comprises contacting a composition comprising the target analyte with the parahydrogen.

Aspect 18. The method of aspect 17, wherein contacting the composition with parahydrogen is carried out for from about 1 s to about 150 s.

Aspect 19. The method of aspect 18, wherein contacting the composition with parahydrogen is carried out for from about 15 s to about 90 s.

Aspect 20. The method of any one of aspects 17-19, wherein contacting the composition with parahydrogen is carried out in a polarization transfer field of from about −30 μT to about 1 T.

Aspect 21. The method of aspect 20, wherein contacting the composition with parahydrogen is carried out in a polarization transfer field of from about 0 to about 0.3 T.

Aspect 22. The method of aspect 20, wherein contacting the composition with parahydrogen is carried out in a polarization transfer field of from about 0.1 mT to about 20 mT.

Aspect 23. The method of any one of aspects 17-22, wherein contacting the composition with parahydrogen comprises bubbling parahydrogen through the composition, delivering parahydrogen through a semipermeable membrane, or any combination thereof.

Aspect 24. The method of aspect 23, wherein the parahydrogen is bubbled at a rate of from about 30 sccm to about 4000 sccm.

Aspect 25. The method of aspect 23, wherein the parahydrogen is bubbled at a rate of from about 60 to about 200 sccm.

Aspect 26. The method of any one of aspects 17-25, wherein the composition further comprises a co-ligand.

Aspect 27. The method of aspect 26, wherein the co-ligand comprises DMSO, ammonia, benzylamine, water, or any combination thereof.

Aspect 28. The method of aspect 26 or 27, wherein the ratio of target analyte to co-ligand is about 5 to 3.3.

Aspect 29. The method of any one of aspects 17-28, wherein the composition further comprises a polarization transfer catalyst.

Aspect 30. The method of aspect 29, wherein the polarization transfer catalyst comprises a metal center coordinated with an organic ligand.

Aspect 31. The method of aspect 30, wherein the metal center comprises iridium, rhodium, cobalt, or any combination thereof.

Aspect 32. The method of aspect 30 or 31, wherein the polarization transfer catalyst comprises an N-heterocyclic carbene-based iridium catalyst, Crabtree's catalyst, 11,3-bis(2,4,6-trimethylphenyl) imidazole-2-ylidene (IMes), a derivative thereof, or any combination thereof.

Aspect 33. The method of any one of aspects 29-32, wherein the composition comprises from about 5 to about 100 mM target analyte, about 1-20 mM of the polarization transfer catalyst, and, if present, about 5-600 mM of the co-ligand.

Aspect 34. The method of aspect 33, wherein the composition comprises from about 30 to about 75 mM target analyte, about 6 mM polarization transfer catalyst, and, if present, about 20 mM DMSO co-ligand.

Aspect 35. The method of aspect 34, further comprising from about 150 to about 575 mM water co-ligand.

Aspect 36. The method of aspect 34, wherein the composition comprises from about 30 to about 60 mM target analyte.

Aspect 37. The method of any one of aspects 17-36, wherein the composition further comprises a solvent.

Aspect 38. The method of aspect 37, wherein the solvent is a deuterated solvent, a protonated solvent, or any combination thereof.

Aspect 39. The method of aspect 37 or 38, wherein the solvent comprises water, methanol, ethanol, chloroform, acetic acid, acetone, acetonitrile, benzene, methylene chloride, pyridine, or any combination thereof.

Aspect 40. The method of any one of aspects 29-39, wherein the target analyte is present in a total amount consisting of a first proportion and a second proportion, wherein the first proportion of the target analyte is free in solution, wherein the second proportion of the target analyte is bound to the polarization transfer catalyst.

Aspect 41. The method of aspect 40, wherein individual molecules can transfer from the first proportion to the second proportion or from the second proportion to the first proportion, and wherein the first proportion and the second proportion can vary.

Aspect 42. The method of any one of the preceding aspects, wherein the target analyte comprises two ¹³C.

Aspect 43. The method of aspect 42, wherein the target analyte is ¹³C₂ pyruvate.

Aspect 44. The method of any one of the preceding aspects, wherein the signal is detected using nuclear magnetic resonance (NMR) spectroscopy or magnetic resonance imaging (MRI).

Aspect 45. A hyperpolarized target analyte prepared according to the method of any one of the preceding aspects.

Aspect 46. A contrast agent comprising the hyperpolarized target analyte of aspect 45.

Aspect 47. A method for diagnosing a disease or monitoring progress of treatment of a disease in a subject, the method comprising:
(a) administering the hyperpolarized target analyte of aspect 45 or the contrast agent of aspect 46 to the subject; and
(b) performing imaging on the subject,
wherein performing imaging enables visualization of the hyperpolarized target analyte in the subject.

Aspect 48. The method of aspect 47, wherein the subject is a mammal.

Aspect 49. The method of aspect 48, wherein the mammal is a human, mouse, rat, pig, hamster, guinea pig, sheep, dog, cat, or horse.

Aspect 50. The method of any one of aspects 47-48, further comprising performing at least one processing or purification step on the hyperpolarized target analyte prior to administering the hyperpolarized target analyte to the subject.

Aspect 41. The method of aspect 50, wherein the at least one processing or purification step comprises filtration, catalyst removal, solvent exchange, pH adjustment, temperature adjustment, or any combination thereof.

Aspect 52. The method of any one of aspects 47-51, wherein the hyperpolarized target analyte is administered to the subject in a single injection.

Aspect 53. The method of any one of aspects 47-51, wherein the hyperpolarized target analyte is administered to the subject continuously for a period of from about 30 seconds to about 30 minutes.

Aspect 54. The method of any one of aspects 47-53, wherein the disease comprises cancer, cardiovascular disease, or a metabolic disorder.

Aspect 55. The method of aspect 54, wherein the cancer comprises prostate cancer, breast cancer, or brain cancer.

Aspect 56. The method of aspect 54, wherein the metabolic disorder comprises diabetes, pyruvate dehydrogenase complex deficiency, or pyruvate carboxylase deficiency.

Aspect 57. The method of any one of aspects 47-56, wherein the imaging is magnetic resonance imaging (MRI).

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary of the disclosure and are not intended to limit the scope of what the inventors regard as their disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### Example 1: Proton-Only Detection of Hyperpolarized ¹³C₂-Pyruvate

### Introduction

Hyperpolarization (HP) has been developed to create high nuclear spin polarization, increasing signal levels in magnetic resonance techniques. Hyperpolarized magnetic resonance imaging (HP MRI) has enabled in vivo imaging of biologically active molecules at physiologically relevant concentration to sense dynamic metabolic processes.

Pyruvate is the most promising ¹³C-hyperpolarized HP substrate to date because it plays a central role in metabolic pathways and it has been shown as a potent biomarker for various diseases, such as cancer, diabetes, cardiovascular disease, and neurological diseases. HP pyruvate is now under evaluation in nearly 40 clinical trials.

Today, HP ¹³C hyperpolarized MRI requires full ¹³C capabilities, for excitation slice selection and detection, which includes RF coils, amplifiers, and RF chains. Very few specialized research scanners have this capability.

Herein is presented a method that can make ¹³C HP MRI compatible with scanners equipped with only proton (¹H) capabilities. This can be achieved with Spin Lock Induced Crossing (SLIC) pulses that are applied on the ¹H channel to transfer hyperpolarization stored in ¹³C₂ singlet state to protons. Previous work has established this possibility on symmetric model spin systems such as ¹³C₂-diphenyldiacetyllene using thermal polarization.

Since then, it has also been shown that the parahydrogen-based hyperpolarization method known as Signal Amplifications by Reversible Exchange (SABRE) is able to directly hyperpolarize long-lived singlet states on a variety of substrates, including pyruvate. SABRE is a particularly fast and inexpensive hyperpolarization method that works directly in room temperature solutions.

Here, SABRE was used to first create hyperpolarized carbon singlet state on 1,2-[¹³C₂]-pyruvate, followed a Spin Lock Induced Crossing (SLIC) pulse sequence to transfer HP from HP carbon singlet to protons of the CH₃ group for detection. Low-fields were used because they are useful for storing hyperpolarization in singlet states. Specifically, at low fields the J-coupling between two spins is often larger than their frequency difference making the singlet state is an eigenstate of the static Hamiltonian. The longer singlet lifetimes offer advantages for imagining and reaction monitoring, because of extended time available for signal detection. A further advantage of low fields is that they do not require expensive magnets compared to today's superconducting NMR and MRI scanners. It is believed that the combination of low-cost MRI with low-cost SABRE HP may establish an affordable molecular imaging platform. In this contribution the need for dedicated heteronuclear channels on low-field scanners is removed. Specifically, it is shown that the long-lived hyperpolarized singlet state of ¹³C₂ pyruvate can be transferred to the protons of the CH₃ group without ¹³C-pulses.

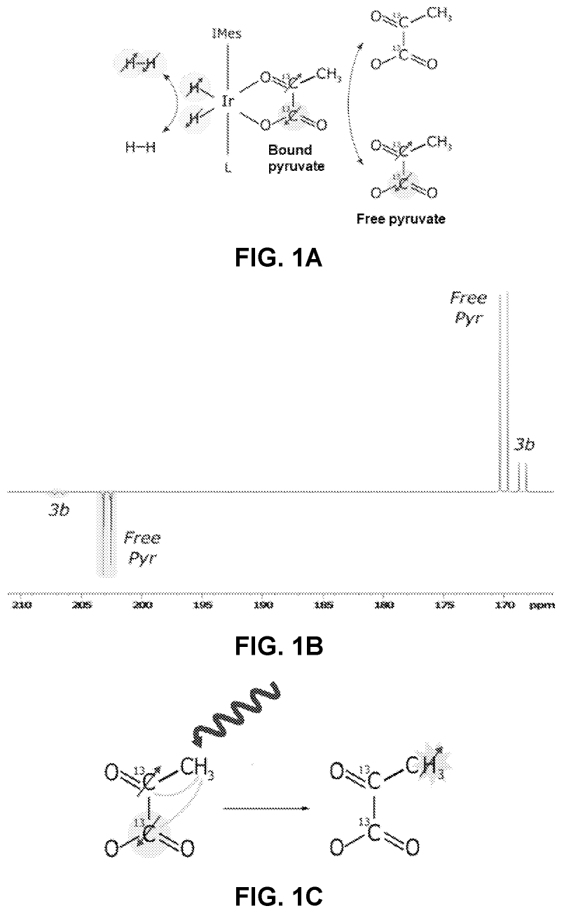

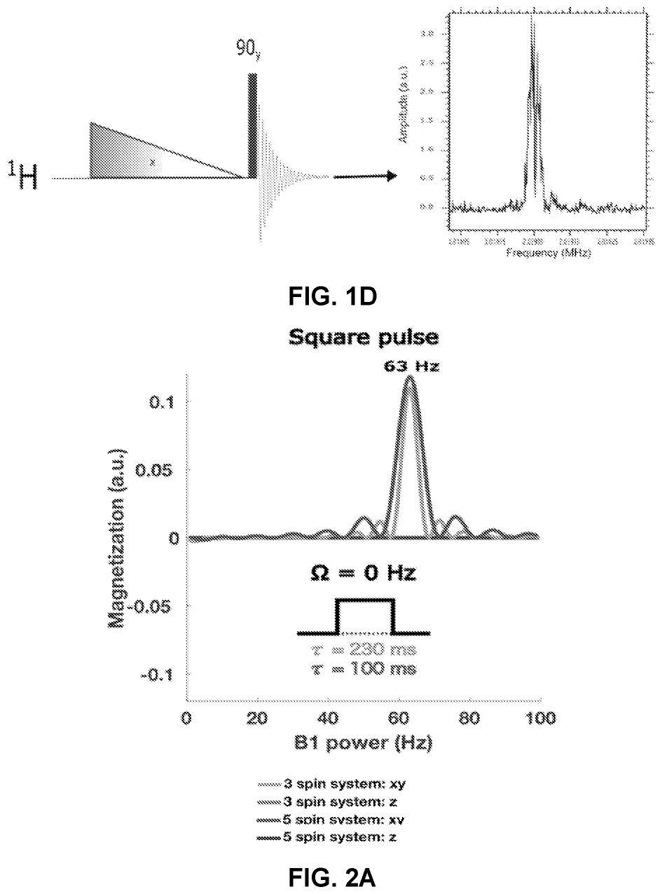

As displayed in FIG. 1A, to hyperpolarize the singlet state of ¹³C₂ pyruvate SABRE is used, where parahydrogen (pH₂) and substrate reversibly bind to a polarization transfer complex (PTC). The hyperpolarization is transferred from bound pH₂-derived hydrides to bound substrate, in the present case—pyruvate. As substrates are in reversible exchange a pool of free HP pyruvate is created in the solution. At the appropriate magnetic field, 1.7 μT in this case, a hyperpolarized ¹³C₂ singlet state is created spontaneously.

To prove the creation of ¹³C₂ singlet state the sample is quickly transferred to a high field (9.4 T) and detect a standard 1D NMR spectrum with a 90 pulse, displayed in FIG. 1B. The observed antiphase spectrum proofs the successful creation of singlet state order: the 2-¹³C peaks at 200 ppm and 1-¹³C peaks at 170 ppm point in opposite directions.

FIG. 1C illustrates the effect of a SLIC pulse applied on the ¹H channel at the frequency of the CH₃ group. The SLIC pulse drives the polarization from hyperpolarized ¹³C₂-singlet state to protons on the CH₃ group where it can be detected without ever using ¹³C RF irradiation.

FIG. 1D shows the experimental implementation where a SLIC pulse with a linear ramp of B₁ power was used. The linear ramp is used to compensate for experimental B₁ inhomogeneities. Those experiments were executed at 48.5 mT and the spectrum shows the resulting proton-only signals of pyruvate acquired at a low-field.

Herein is provided a full theoretical description for polarization transfer from carbon singlet state to protons from CH₃ group via a SLIC pulse applied on the proton channel only. Also provided is a first experimental implementation on a 48.5 mT system that suffers from B₁ and B₀ inhomogeneities.

### Results and Discussion

Theoretical background: The first step is the creation of a hyperpolarized singlet state on ¹³C₂-pyruvate. As detailed in previous literature there are two resonance conditions for the creation of singlet order.

$${J}_{CC} = \pm {J}_{HH} \qquad ( 1 )$$

$$\text{?} . \qquad ( 2 )$$

$$\text{?} \text{indicates text missing or illegible when filed}$$

and

In the present case, Jcc≈60 Hz in the catalyst bound state and J_{HH}≈−10.6 Hz, therefore the first resonance has significantly reduced efficiency and the best hyperpolarization of the singlet order is experimentally obtained by adjusting the magnetic field to 1.7 μT. (The equation above predicts 1.55 μT. Differences between experiment and analytical solution are due to experimental offsets in the magnetic shields.) Once the singlet state is hyperpolarized, the second step, which is described in full detail herein, is the transfer of hyperpolarization to the CH₃ group via SLIC.

All three protons are equivalent in the methyl group of pyruvate. To simplify the analysis, the system is reduced to a 3 spin system by replacing the CH₃ with a single ¹H. This yields 8×8 matrices instead of 32×32. Further below, full simulations on the complete 5-spin system are provided.

The Hamiltonian of the 3-spin system is given as

$${H}_{3 - spin} = {ν}_{C} ( {I}_{1 z} + {I}_{2 z} ) + {ν}_{H} {S}_{z} + {J}_{CC} {I}_{1} \cdot {I}_{2} + \frac{\vert {J}_{{C}^{′} H} - {J}_{C H} \vert}{2} ( {J}_{C H} {I}_{1} \cdot S - {I}_{2} \cdot S ) ++ \frac{{J}_{{C}^{′} H} + {J}_{C H}}{2} ( {I}_{1} \cdot S + {I}_{2} \cdot S ) \qquad ( 3 )$$

where v_{C} is carbon's frequency, v_{H} is proton's frequency, I₁ and I₂ are the spin operators of 1-¹³C and 2-¹³C, while S is the spin operator of ¹H. J_{CC} is the carbon-carbon coupling.

It is also useful to introduce the sum and difference terms of the out-of-pair couplings as

$$Δ {J}_{C H} = \vert {J}_{{C}^{′} H} - {J}_{C H} \vert and \qquad ( 4 )$$

$$Σ {J}_{C H} = {J}_{{C}^{′} H} + {J}_{C H} . \qquad ( 5 )$$

If an RF pulse is applied along the x-direction on resonance with the single proton the RF Hamiltonian can be formulated as:

$${H}_{RF} = {B}_{1} \cdot {S}_{x} \qquad ( 6 )$$

where B₁ is the amplitude of the applied pulse.

Therefore, the total Hamiltonian can be expressed as

$${H}_{total} = {ν}_{C} ( {I}_{1 z} + {I}_{2 z} ) + {ν}_{H} {S}_{z} + {J}_{CC} {I}_{1} \cdot {I}_{2} + \frac{Δ {J}_{C H}}{2} ( {I}_{1} \cdot S - {I}_{2} \cdot S ) + \frac{Σ {J}_{C H}}{2} ( {I}_{1} \cdot S + {I}_{2} \cdot S ) + {γ}_{1 H} {B}_{1} \cdot {S}_{x} \qquad ( 7 )$$

As will be shown in the following, in the case of on resonance RF, efficient hyperpolarization transfer from carbons in the singlet state to the proton is possible if the B₁ power matches the carbon-carbon J-coupling J_{CC}.

To analyze these polarization, transfer dynamics, it is helpful to use the singlet-triplet basis to describe the carbon spin pair.

For the proton, orientation quantized along −x and +x directions is used:

$$\vert {x}_{-} 〉 = \frac{1}{\sqrt{2}} ( \vert α 〉 - \vert β 〉 ) , \vert {x}_{+} 〉 = \frac{1}{\sqrt{2}} ( \vert α 〉 - \vert β 〉 ) \qquad ( 8 )$$

Combining carbon and proton states results in 4×2=8 total states (for example, |S₀x₊ [symbol] ).

Here, part of the total Hamiltonian that illustrates population transfer from |S₀x₊> to |T₀x₋> is focused on:

$$\begin{matrix}\vert {S}_{0} {x}_{+} 〉 \\ \vert {T}_{0} {x}_{-} 〉\end{matrix} \begin{matrix}\begin{matrix}\vert {S}_{0} {x}_{+} 〉 & \vert {T}_{0} {x}_{-} 〉\end{matrix} \\ ( \begin{matrix}\frac{{B}_{1}}{2} - \frac{3}{4} {J}_{{C}^{′} C} & \frac{Δ {J}_{CH}}{4} \\ \frac{Δ {J}_{CH}}{4} & - \frac{{B}_{1}}{2} + \frac{1}{4} {J}_{{C}^{′} C}\end{matrix} )\end{matrix} \qquad ( 9 )$$

This matrix indicates that ΔJ_{CH} can drive population transfer when the difference between diagonal elements in this part of Hamiltonian becomes small. Therefore, if

$$\frac{{B}_{1}}{2} - \frac{3 {J}_{{C}^{′} C}}{4} = - \frac{{B}_{1}}{2} + \frac{{J}_{{C}^{′} C}}{4} , \qquad ( 10 )$$

then the off-diagonal elements can take full effect and rotate the population from |S₀x₊> to |T₀x₋>. This establishes the resonance condition:

$${B}_{1} = {J}_{{C}^{′} C} . \qquad ( 11 )$$

So, if the B₁ power matches the J-coupling, and if it is applied on resonance, then polarization can be transferred to the proton. This analysis is accurate for a 3-spin system and on-resonance RF. The actual experiments are on a 5-spin system with a CH₃ group and suffer from B₁ and B₀ inhomogeneities. In order to understand the effect of additional spins as well as RF offsets, spin dynamics simulations were performed for these more complicated scenarios detailed in the following.

Simulations: The spin evolution was simulated using SPINACH [Ref to spinach JMR 2011, 208,2,179] simulation library version 2.6.5625 in MATLAB (R2021a) as described below.

We explore two different ways to conduct SLIC experiments, for both the 3-spin system (¹³C₂ pair and one proton) and for the 5-spin system (¹³C₂ pair and CH₃), namely, square pulses and adiabatic linear B₁ ramps. Both cases were simulated for on-resonance and off-resonance RF irradiation. The off-resonance case is important to consider because of experimental B₀ inhomogeneities, whereas the adiabatic B₁ ramps are implemented to compensate for experimental B₁ inhomogeneities.

TABLE 1
J-coupling and chemical shift parameters
used to build the respective Hamiltonians

| | ¹H | ¹³C₂ | ¹³C₁ |
|---|---|---|---|
| Chemical shift, ppm | 0 | 30 | 0 |

| | ¹H—¹H | ¹H—¹³C₂ | ¹H—¹³C₁ | ¹³C₁—¹³C₂ |
|---|---|---|---|---|
| J-couplings, Hz | 15 | −4.76 | 1.62 | 61 |

In the simulations, the initial density matrix was a singlet between the two carbons, taking into account the transfer from the μT field, where the singlet order is generated to the 48.5 mT field where acquisition occurs. The resulting density matrix was evolved under the Hamiltonian of the system including the RF-irradiation at 48.5 mT. Square pulses were applied along x on the ¹H channel with specified duration. No additional pulses were simulated after the SLIC pulses. Simply, the magnetization in the transverse plane (x,y) on the proton(s), or magnetization along z are calculated at the end of the SLIC pulses and plotted.

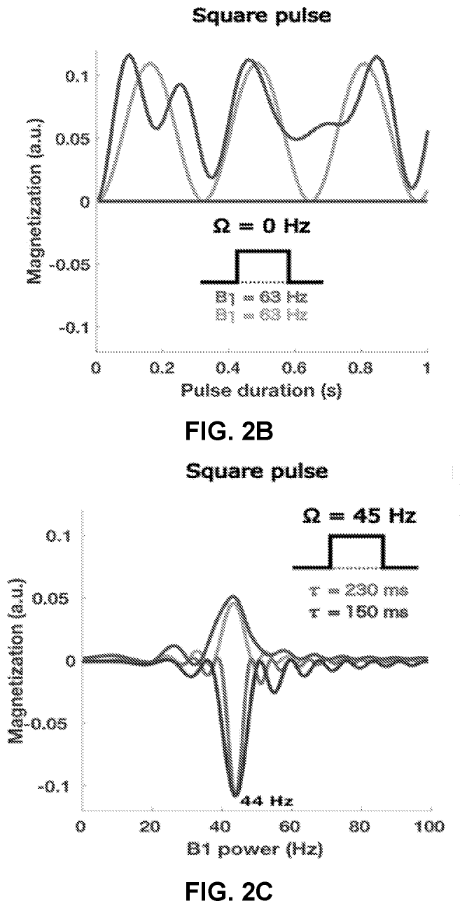

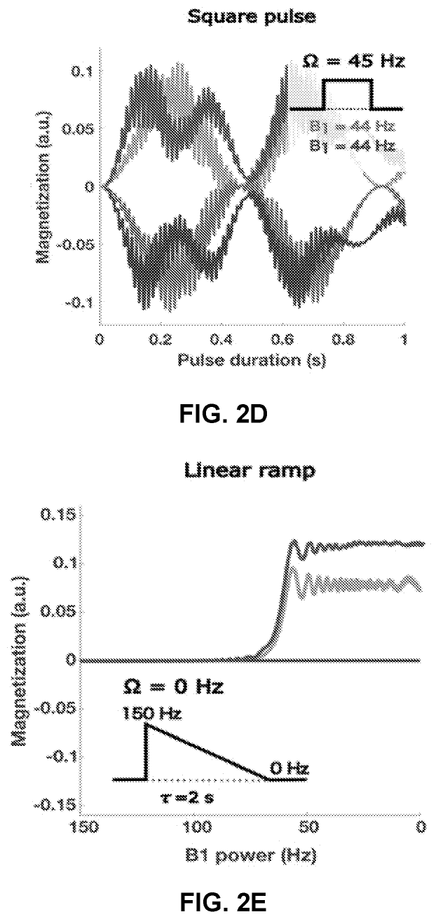

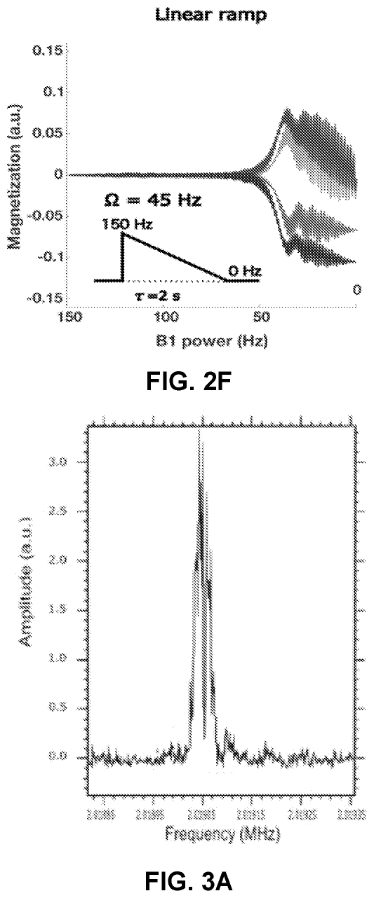

FIGS. 2A-2F show simulations of the most important features of the 3-spin and 5-spin system under SLIC irradiation. Specifically, effects of B₁ power, pulse duration, shape and off-resonance are analyzed for the two spin systems. FIG. 2A examines polarization transfer from the singlet state to ¹H as a function of B₁ power in the on-resonance case (Ω⁰=0). For both, the 3-spin and the 5-spin system, maximum transfer occurs at B₁=63 Hz Hz-corresponding to the resonance condition equation from Eq. 11: B₁=63 Hz≈J_{CC}=61 Hz. The reason for the 2 Hz difference between analytical and simulated outcome is that there is a slight frequency difference between the two carbons, which is not taken into account in the analytical model but is included in the simulations (Δδ=30.1 ppm=15.6 Hz@48.5 mT). Both spin systems show a maximum transfer efficiency at the same B₁ power of 63 Hz.

FIG. 2B shows all the magnetization terms as a function of pulse duration. With on-resonance irradiation with B₁=63 Hz, no z-magnetization is formed. Interestingly, the 5 spin-system, with the CH₃ group reaches the maximum faster, after only 100 ms, the first maximum is achieved, whereas in the three spin system the maximum does not appear until 165 ms. Also, the three spin system shows simple sinusoidal oscillations, whereas the 5 spin system displays a more irregular pattern.

As depicted in FIG. 2C, once an offset is taken into account, magnetization along the z-direction is formed. An RF-offset of Ω=45 Hz was chosen to illustrate these effects. With this offset, the magnetization was calculated along z as well as in the transverse plane (xy) as a function of B₁ power. As illustrated, all magnetization terms reach a maximum at a B₁ power of 44 Hz, where more magnetization is along z compared to transverse (xy). For this simulation the pulse length was chosen at 160 ms because this gives maximum polarization transfers under this off-resonance condition, as illustrated in FIG. 2D. FIG. 2D also shows that off-resonance effects also induce much more rapid oscillations and complicate the control over the polarization transfer process. In this sense, FIG. 2D illustrates the challenges caused by both, B₀ and B₁ inhomogeneities. The simulated behavior indicates that exact control over B1 and B0 is necessary to achieve good polarization transfer, however this may be experimentally challenging.

Because of these challenges, linearly ramped B₁ pulses have been designed, which impart robustness towards B₁ and B₀ inhomogeneities. The linear ramp approach allows for and adiabatic sweep through the resonance conditions that are spread across the sample because of the inhomogeneities. a more robust way. The slow sweep allows for excitation of the dispersed resonances as the B₁ is reduced slowly.

In the simulation, the B₁ amplitude goes from 150 Hz to 0 Hz during 2 s. FIGS. 2E-2F display the various magnetization terms (z, xy) during the pulse on resonance (Ω=0 Hz) and off-resonance (Ω=45 Hz) respectively. It is further demonstrated that xy-magnetization occurs one B₁ pulse amplitude equals 80 Hz region and reaches plateau till the end of the pulse. At the end of the pulse xy-magnetizations were equal to values resulted from square pulses. Similar to the square pulse effects (FIGS. 1A-1B) no z-magnetization was formed in resonance case for adiabatic pulse. In addition, the off-resonance effects (Ω=45 Hz) of the adiabatic pulse (FIG. 2F) were simulated. Once the B₁ pulse amplitude reaches 80 Hz region off-resonance effects transform all xy-magnetizations to the z-magnetizations for both 3 and 5 spin systems. Simulated effects of square and adiabatic pulses allow the conclusion that, in experiments with B₀ and B₁ inhomogeneities (off-resonance case), primarily z-magnetization can be observed.

Experimental Implementation: Based on detailed simulation, experimental implementation and demonstration of polarization transfer from carbon singlet to protons on the methyl group achieved via adiabatic pulse applied only at the ¹H channel only were carried out.

Hyperpolarization carbon singlet state reached its maximum of 1.7 uT in the mu-metal shields. Then, the sample was manually transferred from the field to the low-field spectrometer (B₀=48.5 mT), in which an adiabatic pulse (B₁) was applied at ¹H channel only.

Polarization transfer can occur once the nutation frequency of the ramp is close to the J-coupling constant between the two labeled carbon nuclei. The experimental 48.5 mT setup employed in these proof-of-concept demonstrations suffers from significant B₁ and B₀ inhomogeneities. Magnetic field inhomogeneity for B₀ and B₁ has two sources: non-ideal experimental conditions (sample is not precisely at the center of the magnet bore) and magnetic susceptibility discontinuities in a sample. To compensate these magnetic field inhomogeneities, a linear ramp pulse at ¹H channel was applied with a much higher initial B₁ amplitude than was implemented in simulations.

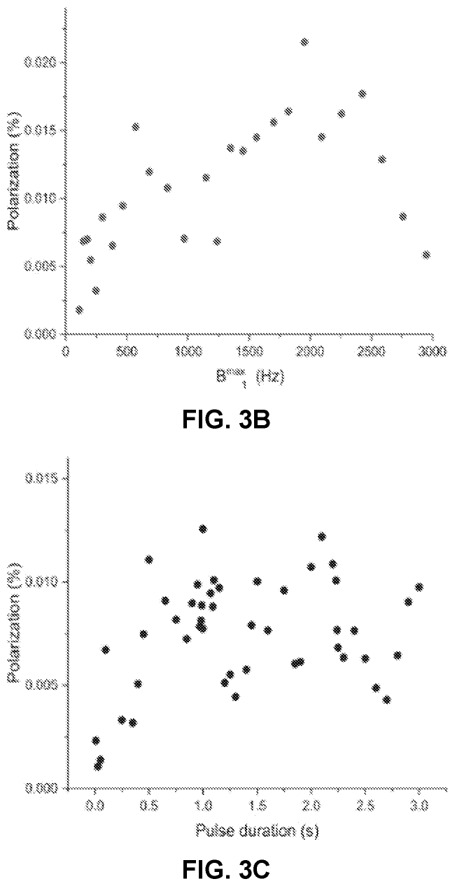

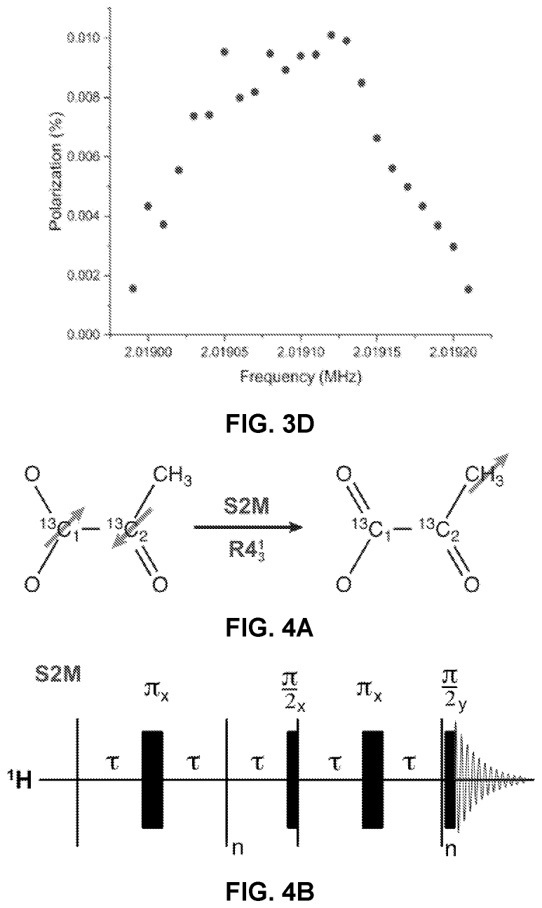

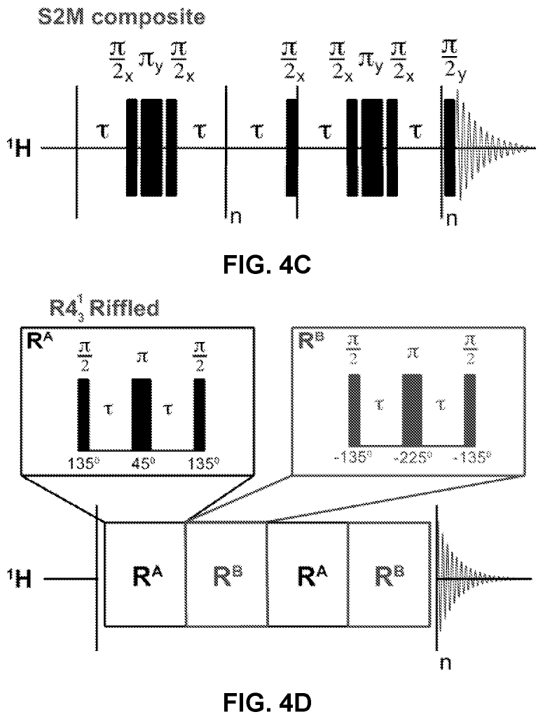

As demonstrated via simulations above, square SLIC pulses are exquisitely sensitive to B₁ power, pulse duration and off-resonance effects. Therefore, adiabatically ramped shapes were implemented that are more immune to these imperfections. Then, the behavior of the system was carefully characterized as a function of B₁ power (FIG. 3B), pulse duration (FIG. 3C) and irradiation frequency (FIG. 3D).

First, FIG. 3A displays a spectrum acquired after a adiabatic ramp followed by a 90° pulse. The spectrum primarily reflects the large B₀ inhomogeneities with an overall width of ˜60 Hz. In the middle of the peak, a hole appears. This hole is the area in the spectrum where the SLIC pulse is actually on-resonance only producing x-y magnetization. Left and right of that whole, the SLIC ramp is off-resonance producing z-magnetization as indicated in the simulations.

All further experiments had 90° pulse at the end of adiabatic pulse to acquire z-magnetization.

Effect of initial B1 amplitude: To explore the effects of the adiabatic pulse slope, a pulse duration of 1 second and frequency 2.01905 MHz was chosen.

The initial value of B₁ determines the slope of the linear ramp; in other words, it controls how much time the pulse would spend at each step exciting a specific frequency. As known from theoretical analysis values of B₁ far from J_{C′C} values do not affect the polarization transfer of interest. Thus, only the last few steps of the linear ramp affect the polarization transfer if initial B₁ value is higher than 500 Hz.

FIG. 3B shows no signal and only noise if the initial pulse amplitude is less than 20 Hz or more than 2500 Hz. The graph has two dips, around 1000 Hz and 2000 Hz. The signal with the initial B₁ from 1500 Hz to 2500 Hz is higher than from 20 Hz to 500 Hz. These dips/oscillations may occur due to manual transfer or field inhomogeneity.

Effect of Pulse Duration: An initial B₁ pulse amplitude equal to 1953 Hz and frequency 2.01905 MHz (optimal parameters from FIG. 3B) were used to explore effects of pulse duration. FIG. 3C depicts strong (a)periodic oscillations similar to FIGS. 2D and 2F from the simulation section in off-resonance cases.

Frequency sweep: A frequency sweep was performed to investigate the effect of frequency offset on the detected signal. A pulse duration of 1 second and frequency of 2.01905 MHz was chosen. The sweep frequency was over 200 Hz. The signal starts to decay once the pulse frequency is less than 2.019025 MHz or more than 2.019125 MHz.

### CONCLUSION

We presented an approach that transfers polarization from the long-lived singlet state of ¹³C₂ pyruvate to methyl pyruvate protons using proton-channel only. This technique allows to combine benefits of hyperpolarization methods. better signal-to-noise ratio, with widely available clinical MRI scanners that have ¹H channel only. This task is accomplished with Spin Lock Induced Crossing (SLIC) pulses that are applied only to the methyl protons, yet access the hyperpolarization stored in the ¹³C₂ singlet state. This method may be applied not only to pyruvate but to other alfa keto acids.

### Experimental Section

Sample preparation: The sample contained 30 mM sodium pyruvate-1-2-[¹⁸C₂] as a substrate, 40 mM dimethyl sulfoxide (DMSO) as a co-ligand, and 6 mM catalyst precursor dissolved in methanol-d4. The samples were prepared by filling 0.5 mL of the stock into standard
mm NMR tubes, then flushed with argon for 1-2 min to remove oxygen, and sealed under an argon atmosphere (WG 1000-8, Wilmad).

Parahydrogen production: The parahydrogen generator was described previously. In brief, a parahydrogen (p-H₂) generator (>99% para-state, 240 psi, at 2 slm (standard liters per meter)) was slightly modified to operate with a closed-loop water-cooling system (CoolPak, Advanced Research Systems) that improves its mobility. A mass-flow controller (SmartTrak 50, SierraInstruments) regulates the p-H₂ gas flow.

Parahydrogen was bubbled through the solution for catalyst activation at 25° C. for 15 min before any experiments. During this time, the solution changed the color from yellow to clear.

Experimentalsetup: SABRE-SHEATH (signal amplification by reversible exchange-Shield Enables Alignment Transfer to Heteronuclei) experiments were conducted in a μ-metal shield (3 layers, ZG-209, Magnetic Shield Corp.).

The degaussing circuitry employed was standard. The required magnetic field in the μT regime was generated by a small coil inside the shield after proper degaussing. The parahydrogen flowed through Teflon tubing submerged in the solution.

We hyperpolarized pyruvate-1-2-[¹⁸C₂] by pressurizing the NMR tube to 100 psi, cooling at 15° C., and bubbling for 60 s with a flow rate set to 150 sccm at 1.7 μT. As soon as the p-H₂ flow was turned off, the sample was transferred to 48.5 mT for detection.

The low magnetic field was generated by a permanent magnet configured in a Halbach array with B₀=0.0485 T (Magritek, Wellington, New Zealand). An RF multi-turn dual saddle-shaped coil was used for the pulse application at the ¹H channel. The NMR probe frequency was 2.01905 MHz.

### Example 2: Immune to Magnetic Inhomogeneity Proton-only Detection of Hyperpolarized ¹³C₂-pyruvate by S2M and R43

### Introduction

NMR hyperpolarization has been developed to create high degrees of nuclear spin polarization approaching order unity compared to polarization of ˜10⁵ at thermal equilibrium. As a result, the hyperpolarization process increases magnetic resonance signals by 4-5 orders of magnitude. Hyperpolarized (HP) biologically compatible molecules can be employed as exogenous contrast agents, which enable in vivo imaging of metabolic activity.

¹³C-labeled pyruvate is the most promising ¹³C-hyperpolarized HP contrast agent because it plays a central role in metabolic pathways of cellular energetics. Aberrant HP ¹³C-pyruvate metabolism has been shown as a potent biomarker for various diseases, such as cancer, diabetes, cardiovascular disease, and neurological diseases. HP pyruvate is now under evaluation in nearly 40 clinical trials according to clinicaltrials.gov. MRI using HP ¹³C-pyruvate has the potential to become next-generation molecular imaging because it provides similar metabolic information as ¹⁸F-flurodeoxyglucose Positron Emission Tomography (¹⁸FDG-PET) scan, but with the added benefit of fast (1-minute) scan time and operation without ionizing radiation.

Currently MRI of HP ¹³C-pyruvate requires full ¹³C capabilities of MRI scanner for excitation, slice selection and detection, which includes specialized RF coils, RF amplifiers, RF chains, and pulse sequences. Only a very few specialized research scanners have this capability out of an estimated 36,000 MRI scanners worldwide. This limitation represents a substantial roadblock for clinical translation of next-generation molecular imaging using HP ¹³C-pyruvate to routine clinical use.

To solve this translational challenge, one strategy is to transfer HP form ¹³C nuclei to spin-spin coupled protons by pulse sequences such as reverse INEPT. this approach has been successfully demonstrated in vivo for HP [1-¹³C]-pyruvate. The key limitation of all previously developed approaches is the requirement to apply RF pulses to the ¹³C nuclei, which most MRI scanners are not equipped for. Herein is presented a new approach for sensing of ¹³C HP pyruvate using MRI scanner equipped with only standard proton (¹H) capabilities. A ¹H S2M and R pulses were employed to transfer hyperpolarization from a singlet state on the carbons of [1,2-¹³C₂]pyruvate to the methyl protons. The result of such proton excitation is hyperpolarization on the methyl protons, which can be detected by standard ¹H RF coils. The presented approach builds on the previous work that has studied polarization transfer in symmetric model spin systems such as ¹³C₂-diphenyldiacetyllene using thermally polarized ¹³C₂ singlet order.

Since then, it has also been shown that the parahydrogen-based hyperpolarization method known as Signal Amplification by Reversible Exchange (SABRE) can directly hyperpolarize long-lived singlet states on a variety of substrates, including [1,2-¹³C₂]pyruvate.

SABRE relies on simultaneous exchange of parahydrogen (p-H₂) and to-be-hyperpolarized substrate, e.g., [1,2-¹³C₂]pyruvate studied here.

SABRE is a fast (˜1-minute buildup time) and inexpensive (<$15,000 equipment cost) hyperpolarization method that spontaneously and directly transfers polarization from p-H₂-derived hydrides to nuclear spins of substrate. Here, SABRE was employed to first create a HP ¹³C₂ singlet state on [1,2-¹³C₂]pyruvate, followed a Spin Lock Induced Crossing (SLIC) pulse to transform the HP singlet to NMR-observable proton magnetization on the methyl group. To preserve the ¹³C₂ singlet state in ¹³C₂ pyruvate it is necessary to remain at low magnetic fields. Sufficiently low-fields preserve the strong coupling regime, where the ¹³C-¹³C spin-spin-coupling (¹J_{13C-13C}˜60 Hz) between the two ¹³C spins is greater than their chemical shift difference (i.e., the resonance frequency of 1-¹³C and 2-¹³C pyruvate spins). In this strong-coupling regime the singlet state remains close to an eigenstate of the static nuclear spin Hamiltonian. Of note, low field magnets are cheap and do not require expensive cryogens (sometimes in short supply) unlike today's high-field superconducting NMR and MRI scanners. Overall, this work contributes to the long-term goal of improving access to next-generation molecular imaging using the combination of low-field MRI with high-throughput pyruvate hyperpolarization. This combination may establish an affordable molecular imaging platform. Herein, HP pyruvate sensing is demonstrated using a low-field, 48.5 mT, MRI scanner only using the proton RF chain and pulse sequence without any ¹³C-related hardware and software.

FIG. 1A shows a scheme of polarization transfer from ¹³C₁-¹³C₂ singlet state to CH₃ group protons after applying S2M, S2M composite, R4₃¹ pulses only on ¹H channel. The S2M pulse sequence involves a two spin-echo trains separated by a 90° pulse (FIG. 1B). Each echo train is repeated n times with a time delay, T. The S2M pulse sequence generates z-magnetization on CH₃ protons, therefore, it is necessary to apply 90° pulses after S2M pulses to convert polarization to xy-plane before acquisition. The S2M composite pulse sequence use compensated 180° rotations to ensure the high accuracy of the inversions required during the pulse train (FIG. 1C). A 180ₓ° pulse is implemented by composite [90ₓ°-180_{y}°-90ₓ°] pulse. R4₃¹ pulses are relatively new pulse sequence originally developed to implement electron-to-nuclear polarization transfer in diamond nitrogen-vacancy magnetometry. As shown in FIG. 1D, this pulse sequence consists of four blocks, R^{A}-R^{B}-R^{A}-R^{B}-R^{A} block three hard pulses, 90° pulse with phase 135°, 180° pulse with a phase 45°, and 90° pulse with phase 135°. Pulses are separated by time delay, T. R^{B} block three hard pulses, 90° pulse with phase −135°, 180° pulse with a phase 225°, and 90° pulse with phase −135°. Pulses are separated by time delay, T, and repeated n times.

### Materials and Methods

Sample Preparation: Catalyst precursor [IrCl(COD)IMes][COD=cyclooctadiene, IMes=1,3-bis(2,4,6-trimethylphenyl)imidazole-2-ylidene]was synthesized as described previously in accord the procedure described in the literature. The sample contained 30 mM sodium [1,2-¹³C₂]pyruvate (Sigma-Aldrich-Isotec P/N 493392) as substrate, 40 mM dimethyl sulfoxide as a co-ligand, and 6 mM catalyst precursor, all dissolved in methanol-d₄. The samples were prepared by filling 0.6 mL of the stock into standard 5 mm NMR tubes (WG 1000-8, Wilmad), then flushed with argon for 1-2 minutes to remove trapped oxygen and sealed under an argon atmosphere.

Experiments: The p-H₂ generator described in Example 1. was employed to produce 98.5% p-H₂. A mass-flow controller (SmartTrak 50, SierraInstruments) regulated the p-H₂ gas flow with flow rate set to 70 standard cubic centimeter per minute (sccm). The total p-H₂ pressure in the NMR tube during SABRE experiments was set to 8 bar. Parahydrogen was bubbled through the solution for catalyst activation at 10° C. for 10 min before any experiments. Upon catalyst activation, the solution changes from yellow to clear solution.

Hyperpolarization of ¹³C₂ singlet state of [1,2-¹³C₂]pyruvate: SABRE-SHEATH (signal amplification by reversible exchange-Shield Enables Alignment Transfer to Heteronuclei) experiments were conducted in a Hyperpolarizer (ref) equipped with a μ-metal shield (3 layers, ZG-209, Magnetic Shield Corp.). The degaussing circuitry employed here was described previously⁴³. The required magnetic field in the μT regime is generated by a small coil inside the shield after proper degaussing⁴³. 1/16″ OD, 1/32″ ID Teflon tubing submerged in the solution.

Sodium [1,2-¹³C₂]pyruvate was hyperpolarized by pressurizing the NMR tube to 8 bar total p-H₂ pressure while bubbling p-H₂ for 60 s with a flow rate set to 150 sccm at 1.7 μT. As soon as the p-H₂ flow was turned off, the sample was transferred to a 48.5 mT MRI device for detection (2-4 seconds time delay between cessation of p-H₂ flow and initiation of polarization transfer sequence).

The low magnetic field was generated by a permanent magnet configured in a Halbach array with B₀=48.5 mT (Magritek, Wellington, New Zealand). ARF multi-turn solenoid coil was used for the pulse application on the ¹H channel. The NMR probe frequency is 2.01885 MHz. The S2M, S2M composite, R4₃¹ pulse was implemented as described previously.

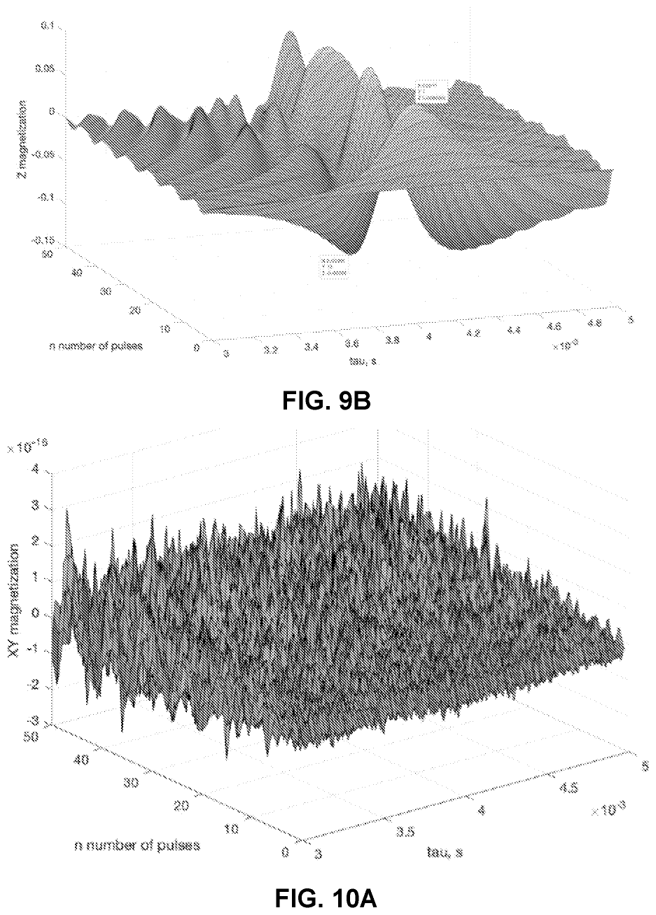

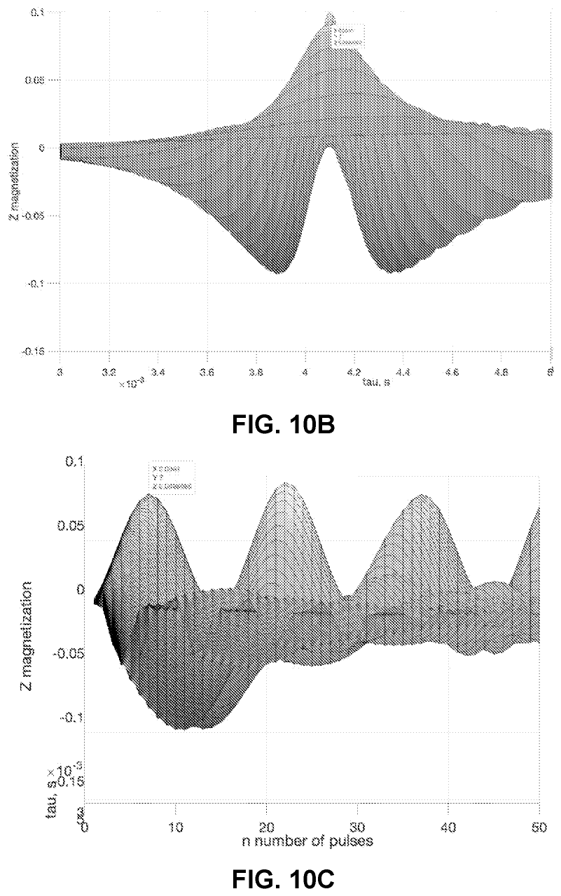

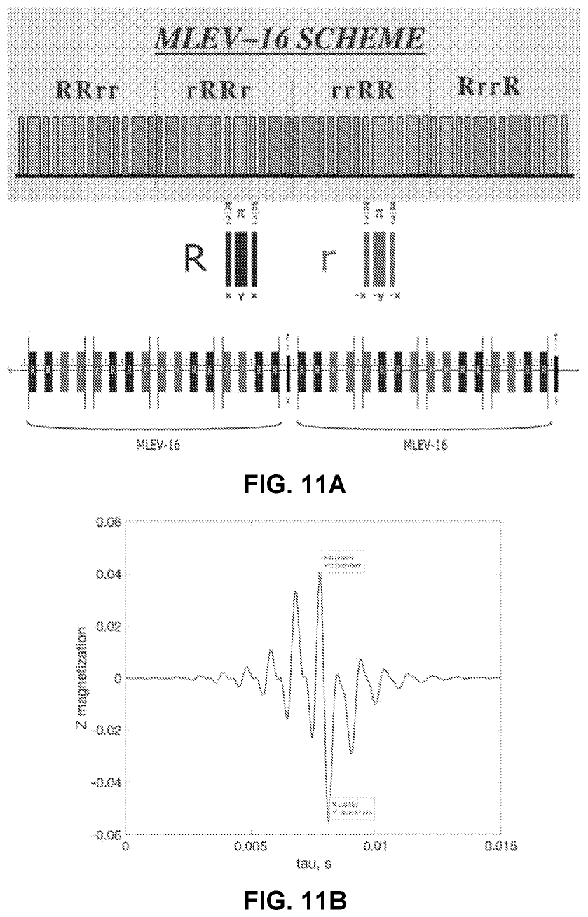

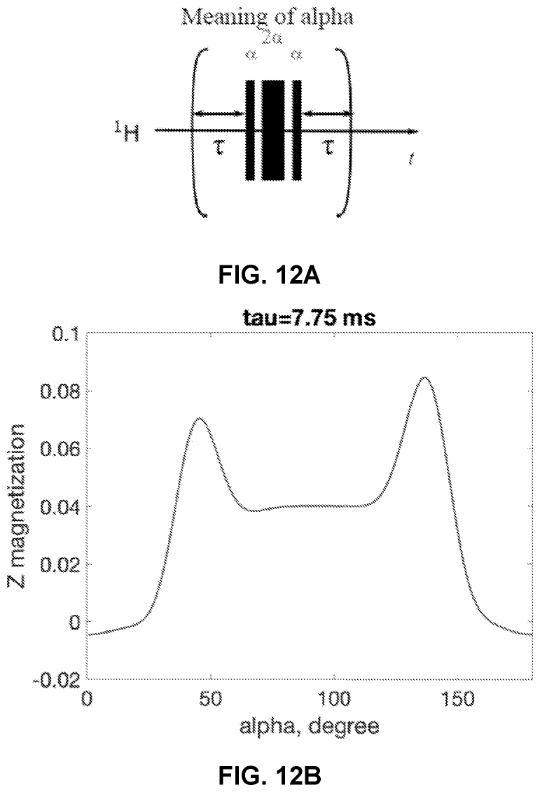

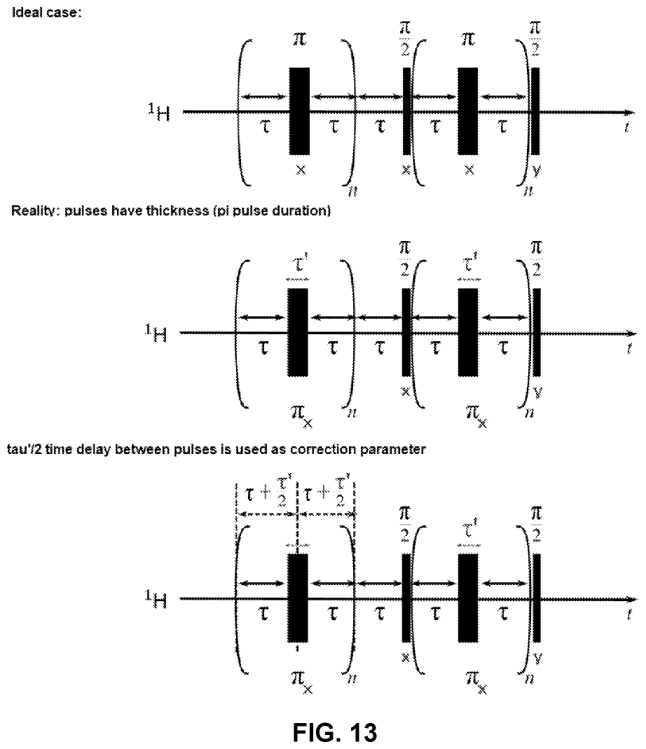

Simulations: The spin evolution was simulated using SPINACH simulation library version 2.6.5625 in MATLAB (R2021a) as described in FIGS. 9A-13.

### Results and Discussion

Once the ¹³C₂ singlet state is hyperpolarized, the next step is the transfer of hyperpolarization to the CH₃ group via series of hard 90° and 180° pulses.

First, the effects of S2M, S2M composite, and R4₃¹ pulse sequence on 5-spin ¹³C₂-pyruvate system (¹³C₁, ¹³C₂, and three protons on CH₃ group) were simulated.

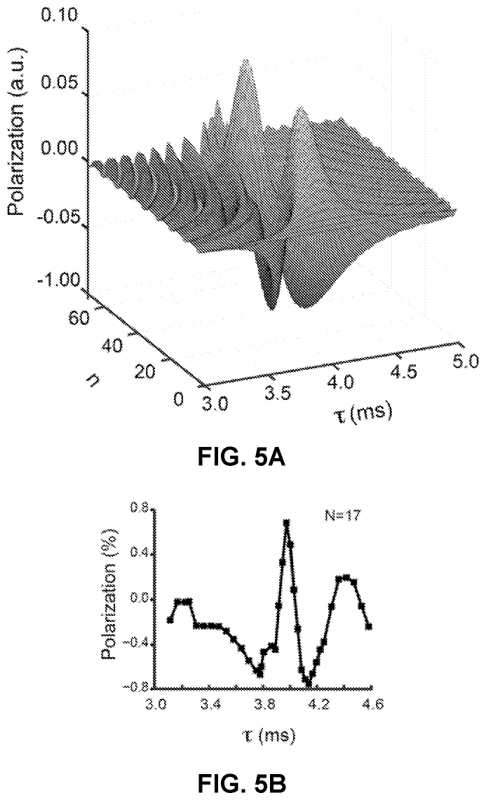

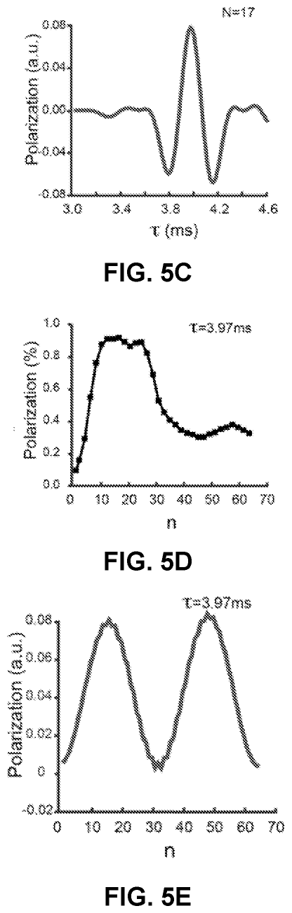

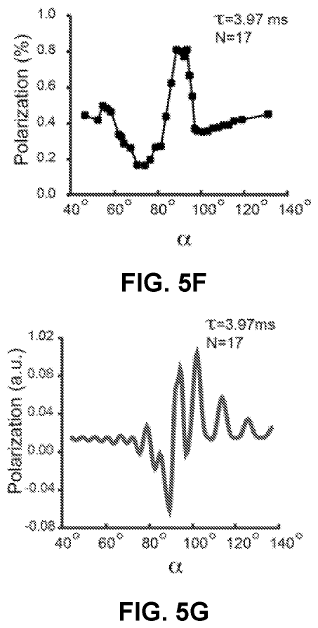

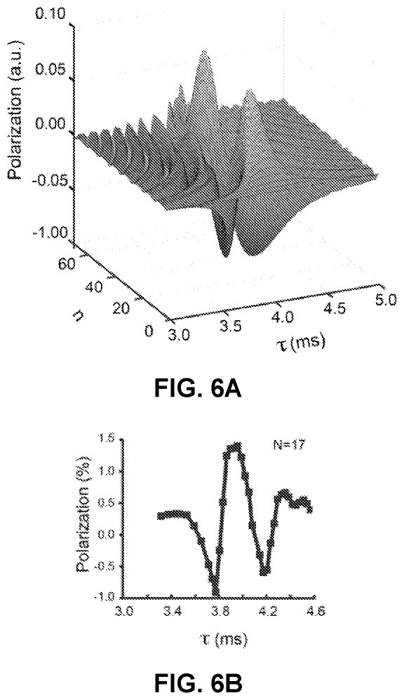

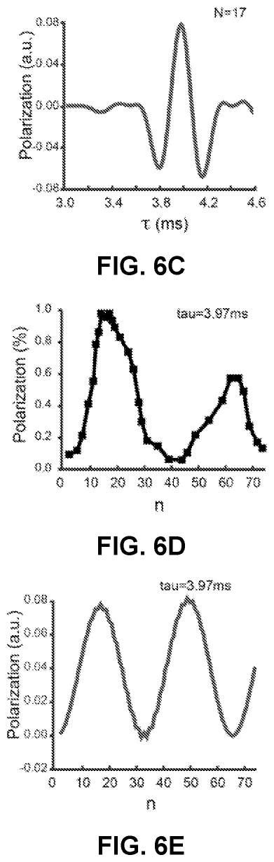

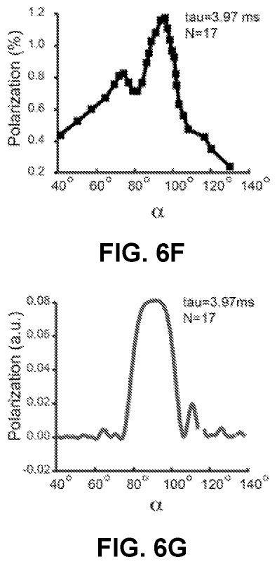

FIG. 5A has a 3D plot on how generated magnetization on CH₃ group protons after S2M pulse sequence depends on time delay, r, and number of cycles, n. The S2M plot has peaks with periodic pattern. For these experiments, one peak at n=17 and T≈3.97 ms was focused on. The experimental setup does not allow running multidimensional tests, thus, a run T sweep was run, followed by n sweep. For the T sweep, a fixed value of number of cycles (n=17) was used and present results plot on FIG. 5B. The T sweep experimental data is in a good agreement with simulation FIG. 5C. The maximum value of polarization was reached at T=3.97 ms; this value was used to run n sweep (FIG. 5D). FIG. 5E shows simulation for S2M n sweep. The experimental data shows two peaks at n≈17 and much smaller at n≈58, whereas simulations show two peaks n=17 and n=48. This mismatch can be explained by looking at 90° angle sweeps both experimental and simulations (FIGS. 5F-5G). As seen at FIG. 5G, the S2M pulse sequence is very sensitive to any inaccuracies in pulse calibrations. A few degrees off could lead to signal loss. Overtime, with number of cycle repetition is being large then, this error in pulse angle accumulates which leads to deviations in n sweep from simulations. To overcome this issue, an S2M composite pulse sequence that transform 180ₓ° pulse into pulse composite [90ₓ°-180_{y}°-90ₓ°] was used. In case of perfectly calibrated 90° pulses, the effect of applying one 180ₓ° is equivalent to composite 90ₓ°-180_{y}°-90ₓ° pulses. Therefore, the simulations for S2M composite (FIGS. 6A, 6C, and 6E) are identical to simulations for regular S2M pulses (FIGS. 5A, SC, and 5E). However, in the presence of pulse calibration errors composite 90ₓ°-180_{y}°-90ₓ° pulses are designed to diminish these errors. FIGS. 6B-6C show both experimental and simulation data for T sweep for S2Mcomposite pulses. Comparing the experimental S2M (FIG. 5B) and composite S2M results (FIG. 6B), it can be seen that the composite S2M produces significantly higher polarization (almost two-fold) and the match with simulation is better. FIGS. 6D-6E show both experimental and simulation data for n sweep for S2Mcomposite pulses. In experimental data first peak n˜17 is in good agreement with simulations, whereas second peak at n˜60 is still smaller than the first peak, but larger than second peak from n sweep of regular S2M pulses. FIGS. 6F-6G show that S2M composite can tolerate ±10⁰ error of 90° pulse angle miscalibration.

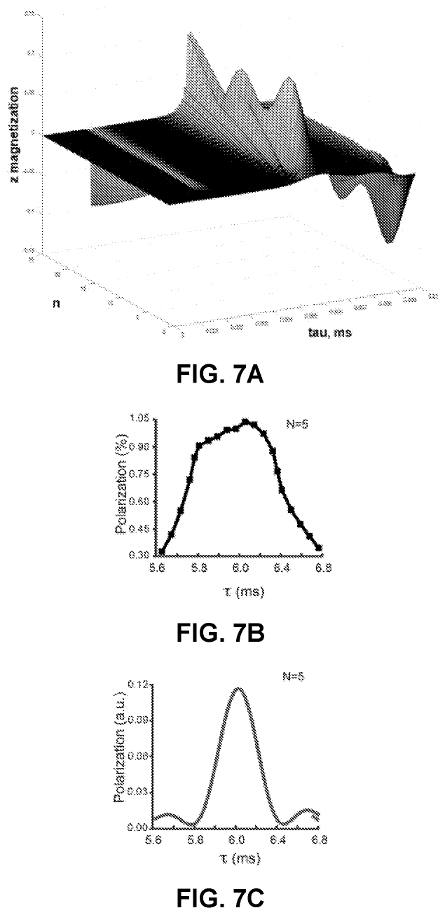

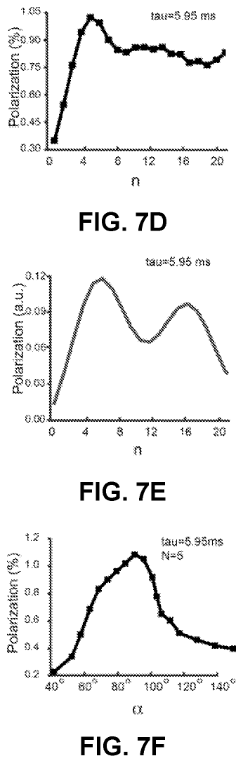

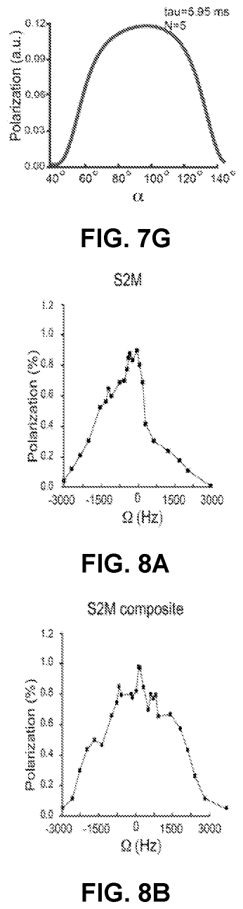

In addition to S2M and S2M composite pulse sequences, an R4₃¹ pulse sequence was implemented. Simulation of the effect of R4₃¹ pulse sequence is shown in FIG. 7A. For the experiments, a slice was taken from 3D plot, to get a τ sweep with fixed number of R4₃¹ cycles (n=5). These experimental data is in good agreement with simulation FIGS. 7B-7C. The maximum value of polarization was reached at T=5.95 ms; this value was used for n sweep (FIG. 7D). FIG. 7E shows simulation for R4₃¹ n sweep. FIGS. 7F-7G show that R4₃¹ pulse sequence outperforms S2M composite pulse sequence in case of calibration errors. R4₃¹ can tolerate ±25° error of 90° pulse angle miscalibration.

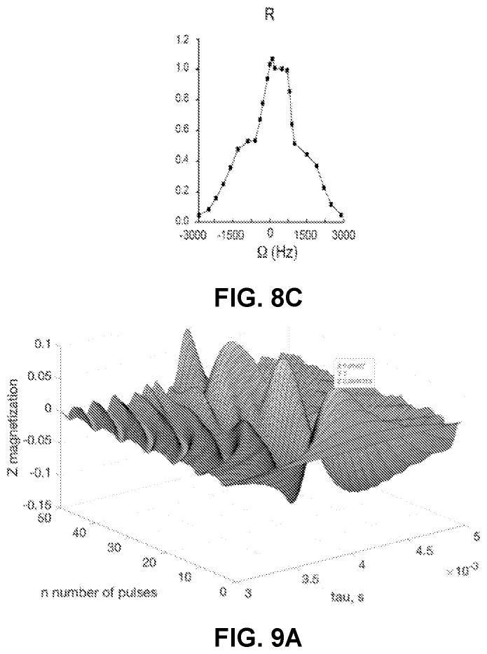

FIGS. 8A-8C show how immune S2M, S2M composite, R4₃¹ pulse sequences to pulse frequency offset. S2M composite and R4₃¹ is better than regular S2M. S2M can operate within the range of −750 Hz to 300 Hz, whereas S2M composite can operate within the range frequency offset of −1500 to 1500 Hz. R4₃ is suitable for −1000 to 1000 Hz frequency rage as well. It is a big advantage compared to SLIC pulses that can tolerate −150 to 150 Hz offset range.

### Conclusion

In summary, herein an approach is presented that transfers polarization from the ¹³C₂-singlet state of [1,2-¹³C₂]pyruvate to methyl pyruvate protons using the proton-channel only of a low-field MRI scanner. This technique allows to combine benefits of hyperpolarization methods and long ¹³C-polarization lifetimes with MRI scanners that only have ¹H channels. The polarization transfer is accomplished with S2M, S2M composite, and R pulses that are applied only to the methyl protons of [1,2-¹³C₂]pyruvate, even though the hyperpolarization is stored in the ¹³C₂ singlet state. In both simulations and experiments the effects of S2M, S2M composite, and R pulse time delay, number of repetition, 90⁰ pulse angle and frequency were explored. Experiments presented employed the non-optimized setup with severe B₁ and B₀ inhomogeneities of the 48.5 mT scanner. The presented method can likely be expanded to other metabolically relevant molecules with similar α-ketocarboxylates such as α-ketoglutarate.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

### REFERENCES

1. Adelabu, I.; et al. Order-Unity 13C Nuclear Polarization of [1-13C]Pyruvate in Seconds and the Interplay of Water and SABRE Enhancement. ChemPhysChem 2022, 23 (2).
2. Ariyasingha, N. M.; et al. Quasi-Resonance Fluorine-19 Signal Amplification by Reversible Exchange. Journal of Physical Chemistry Letters 2019, 10 (15), 4229-4236.
3. Bae, J. et al, Science Advances 2018, 9, doi: 10.1126/sciadv.aar2978.
4. Barskiy, D. A.; et al. The Feasibility of Formation and Kinetics of NMR Signal Amplification by Reversible Exchange (SABRE) at High Magnetic Field (9.4 T). J Am Chem Soc 2014, 136 (9), 3322-3325.
5. Chekmenev, E. Y.; et al. Hyperpolarized 1H NMR Employing Low y Nucleus for Spin Polarization Storage. J Am Chem Soc 2009, 131 (9), 3164-3165.
6. Coffey, A. M.; et al. Low-Field MRI Can Be More Sensitive than High-Field MRI. Journal of Magnetic Resonance 2013, 237, 169-174.
7. Cowley, M. J.; et al. Iridium N-Heterocyclic Carbene Complexes as Efficient Catalysts for Magnetization Transfer from Para-Hydrogen. J Am Chem Soc 2011, 133 (16), 6134-6137.
8. DeVience, S. J.; et al. Preparation of Nuclear Spin Singlet States Using Spin-Lock Induced Crossing. Physical Review Letters 2013, 111 (17).
9. DeVience, S. J. et al, ChemPhysChem 2021, 22, 2128-2137.
10. Eills, J. Advances in Parahydrogen-Enhanced Nuclear Magnetic Resonance; 2019.
11. Feng, Y. et al, Journal of Chemical Physics 2014, 141, DOI 10.1063/1.4896895.
12. Feng, Y. et al, Journal of the American Chemical Society 2013, 135, 9632-9635.
13. Feng, Y.; et al. Long-Lived Polarization Protected by Symmetry. Journal of Chemical Physics 2014, 141 (13).
14. Gallagher, F. A.; et al. Imaging Breast Cancer Using Hyperpolarized Carbon-13 MRI. Proceedings of the National Academy of Sciences 2020, 117 (4), 2092-2098.
15. Gallagher, F. A. et al, Proc. Natl. Acad. Sci. USA, 2009, 106, 19801-19806.
16. Grist, J. T.; et al. Quantifying Normal Human Brain Metabolism Using Hyperpolarized [1-13C]Pyruvate and Magnetic Resonance Imaging. Neuroimage 2019, 189, 171-179.
17. Grist, J. T. et al, Journal of Cerebral Blood Flow and Metabolism 2020, 40, 1137-1147.
18. Hogben, H. J.; et al. Spinach—A Software Library for Simulation of Spin Dynamics in Large Spin Systems. Journal of Magnetic Resonance 2011, 208 (2), 179-194.
19. lali, W/et al., Angewandte Chem Int. Ed. Engl., 2019, 22, 10271-10275.
20. Joalland, B.; et al. Magnetic Shielding of Parahydrogen Hyperpolarization Experiments for the Masses. Magnetic Resonance in Chemistry 2021, 59 (12), 1180-1186.
21. Kurhanewicz, J.; et al. Hyperpolarized 13C MRI: Path to Clinical Translation in Oncology. Neoplasia (United States). Neoplasia Press, Inc. Jan. 1, 2019, pp 1-16.
22. Larson, P. E. Z. et al, NMR in Biomedicine 2018, 31, DOI 10.1002/nbm.3997.
23. Laustsen, C. et al, Diabetes/Metabolism Research and Reviews 2013, 29, 125-129.
24. Laustsen, C.; et al. Hyperpolarized Singlet NMR on a Small Animal Imaging System. Magn Reson Med 2012, 68 (4), 1262-1265.
25. Lewis, A. J. M. et al, Cardiovascular Drugs and Therapy 2020, 34, 231-240.
26. Miloushev, V. Z.; et al. Metabolic Imaging of the Human Brain with Hyperpolarized 13C Pyruvate Demonstrates 13C Lactate Production in Brain Tumor Patients. Cancer Research 2018, 78 (14), 3755-3760.
27. Morris, G. A.; et al. Enhancement of Nuclear Magnetic Resonance Signals by Polarization Transfer. J Am Chem Soc 1979, 101 (3), 760-762.
28. Nantogma, S.; et al. Clinical-Scale Production of Nearly Pure (>98.5%) Parahydrogen and Quantification by Benchtop NMR Spectroscopy. Analytical Chemistry 2021.
29. Nelson, S. J.; et al. A. Metabolic Imaging of Patients with Prostate Cancer Using Hyperpolarized [1-¹³C]Pyruvate. Sci Transl Med 2013, 5 (198), 198ra108.
30. Pileio, G.; et al. Storage of Nuclear Magnetization as Long-Lived Singlet Order in Low Magnetic Field. Proc Natl Acad Sci USA 2010, 107 (40), 17135-17139.
31. Roy, S. S. et al, Angewandte Chemie 2016, 128, 15871-15874.
32. Roy, S. S. et al, Journal of Chemical Physics 2020, 152, DOI 10.1063/1.5132308.
33. Sabba, M.; et al. Symmetry-Based Singlet-Triplet Excitation in Solution Nuclear Magnetic Resonance. 2022.
34. Sarkar, R.; et al. Proton NMR Of15N-Choline Metabolites Enhanced by Dynamic Nuclear Polarization. J Am Chem Soc 2009, 131 (44), 16014-16015.
35. Shen, K. et al, Angewandte Chemie 2017, 129, 12280-12284.
36. Tayler, M. C. D.; et al. Instrumentation for Nuclear Magnetic Resonance in Zero and Ultralow Magnetic Field. 2017.
37. Theis, T. et al, Journal of Chemical Physics 2014, 140, DOI 10.1063/1.4851337.
38. Theis, T. et al, Science Advances 2016, 2, DOI 10.1126/sciadv.1501438.
39. Theis, T.; et al. Quasi-Resonance Signal Amplification by Reversible Exchange. Journal of Physical Chemistry Letters 2018, 9 (20), 6136-6142.
40. Tickner, B. J. et al, Catalysis Science and Technology 2020, 10, 1343-1355.
41. Tomhon, P.; et al. Temperature Cycling Enables Efficient 13 C SABRE-SHEATH Hyperpolarization and Imaging of [1-13 C]Pyruvate.
42. Topping, G. J.; et al. Acquisition Strategies for Spatially Resolved Magnetic Resonance Detection of Hyperpolarized Nuclei. Magnetic Resonance Materials in Physics, Biology and Medicine. Springer Apr. 1, 2020, pp 221-256.
43. Truong, M. L.; et al. Sub-Second Proton Imaging of 13C Hyperpolarized Contrast Agents in Water. Contrast Media and Molecular Imaging 2014, 9 (5), 333-341.
44. Vazquez-Serrano, L. D.; et al. The Search for New Hydrogenation Catalyst Motifs Based on N-Heterocyclic Carbene Ligands. Inorganica Chim Acta 2006, 359 (9), 2786-2797.
45. Wang, J.; et al. Dynamic 1H Imaging of Hyperpolarized [1-13C]Lactate in Vivo Using a Reverse INEPT Experiment. Magnetic Resonance in Medicine 2018, 79 (2), 741-747.
46. Wang, Z. J. et al, Radiology 2019, 291, 273-284.
47. Wilson, D. M. et al, Journal of Magnetic Resonance 2010, 205, 141-147.
48. Zhang, G. et al, Angewandte Chemie 2019, 131, 11235-11241.

1. A method for proton-only detection of a hyperpolarized spin ½ nucleus in a target analyte, the method comprising:
(a) hyperpolarizing parahydrogen;
(b) transferring magnetization from the parahydrogen to a spin ½ nucleus in a target analyte;
(c) applying a pulse sequence on a proton channel, wherein the pulse sequence drives polarization from a singlet state in the spin ½ nucleus to at least one proton coupled to the spin ½ nucleus in the target analyte or to another coupled spin; and
(d) detecting a signal from the at least one proton.

2. The method of claim 1, wherein the spin ½ nucleus comprises ¹³C, ¹⁵N, ¹⁹F, ²⁹Si, ³P, or a combination thereof.

3. The method of claim 1, wherein the pulse sequence comprises spin lock induced crossing (SLIC), magnetization to singlet (M2S), singlet to magnetization (S2M), S2M composite, R4₃¹, or any combination thereof.

4. The method of claim 3, wherein the pulse sequence is S2M, the method further comprising applying a 90° pulse following the S2M pulse.

5. The method of claim 1, wherein the target analyte comprises metabolite, a drug molecule, a vitamin, a pyruvate analog, a combination thereof, or a salt thereof.

6. (canceled)

7. The method of claim 5, wherein the pyruvate analog comprises pyruvate, oxaloglutarate, oxaloacetate, phenyl pyruvate, 2-oxo-butyrate, 2,3-diketogluatarate, 2-oxo-adipate, or any combination thereof.

8. The method of claim 5, wherein the target analyte comprises acetonitrile, benzonitrile, α-cyano-4-hydroxycinnamic acid (CHCA), alectinib, metronidazole, dichloropyridazine, nicotinamide, imidazole, adenine, diphenyldiazene, diazirine, or any combination thereof.

9. The method of claim 5, wherein the target analyte includes a Schiff base, an sp² hybridized nitrogen atom, or any combination thereof.

10. The method of claim 1, wherein transferring magnetization comprises a parahydrogen induced polarization (PHIP) mechanism, wherein the PHIP mechanism comprises hydrogenation, signal amplification by reversible exchange (SABRE), or any combination thereof.

11.-16. (canceled)

17. The method of claim 1 wherein transferring magnetization from the parahydrogen to the target analyte comprises contacting a composition comprising the target analyte with the parahydrogen.

18.-19. (canceled)

20. The method of claim 17, wherein contacting the composition with parahydrogen is carried out in a polarization transfer field of from about −30 μT to about 1 T.

21.-25. (canceled)

26. The method of claim 17, wherein the composition further comprises a co-ligand, wherein the co-ligand comprises DMSO, ammonia, benzylamine, water, or any combination thereof.

27.-28. (canceled)

29. The method of claim 17, wherein the composition further comprises a polarization transfer catalyst, wherein the polarization transfer catalyst comprises a metal center comprising iridium, rhodium, cobalt, or any combination thereof, coordinated with an organic ligand.

30.-31. (canceled)

32. The method of claim 29, wherein the polarization transfer catalyst comprises an N-heterocyclic carbene-based iridium catalyst, Crabtree's catalyst, 11,3-bis(2,4,6-trimethylphenyl) imidazole-2-ylidene (IMes), a derivative thereof, or any combination thereof.

33.-41. (canceled)

42. The method of claim 1, wherein the target analyte comprises two ¹³C.

43. (canceled)

44. The method of claim 1, wherein the signal is detected using nuclear magnetic resonance (NMR) spectroscopy or magnetic resonance imaging (MRI).

45. A hyperpolarized target analyte prepared according to the method of claim 1.

46. (canceled)

47. A method for diagnosing a disease or monitoring progress of treatment of a disease in a subject, the method comprising:
(a) administering the hyperpolarized target analyte of claim 45 to the subject; and
(b) performing imaging on the subject,
wherein performing imaging enables visualization of the hyperpolarized target analyte in the subject.

48.-53. (canceled)

54. The method of claim 47, wherein the disease comprises cancer, cardiovascular disease, or a metabolic disorder.

55. (canceled)

56. (canceled)

57. The method of claim 47, wherein the imaging is magnetic resonance imaging (MRI).
